(19) United States
(12) Patent Application Publication
(10) Pub. No.: US 2026/0343990 A1
(43) Pub. Date: Oct. 29, 2026

(54) SEMICONDUCTOR STRUCTURE WITH PATTERNED STRUCTURE AND METHOD FOR MANUFACTURING THE SAME

(71) Applicant: TAIWAN SEMICONDUCTOR MANUFACTURING COMPANY, LTD., Hsinchu (TW)

(72) Inventors: Shih-Chien LIU, Hsinchu (TW); Chia-Wei CHEN, Hsinchu (TW); Yao-Chung CHANG, Hsinchu (TW); Chun-Lin TSAI, Hsinchu (TW)

(73) Assignee: TAIWAN SEMICONDUCTOR MANUFACTURING COMPANY, LTD., Hsinchu (TW)

(21) Appl. No.: 19/193,325

(22) Filed: Apr. 29, 2025

(51) Int. Cl. H10D 64/00; H10D 30/01; H10D 30/47; H10D 62/824

(52) U.S. Cl. CPC H10D 64/111; H10D 30/015; H10D 30/475; H10D 62/824

(57) ABSTRACT

A semiconductor structure includes a channel layer, a barrier layer, a source electrode, a gate electrode, a drain electrode, a barrier unit, and a field plate unit. The barrier layer is located on the channel layer. The barrier layer has a top surface opposite to the channel layer, and the top surface extends along an X direction. The source electrode, the gate electrode and the drain electrode are disposed on the barrier layer, and are spaced apart along the X direction in such order. The barrier unit is disposed on the top surface between the gate electrode and the drain electrode. The barrier unit has a content of a Group III element changing along the X direction. The field plate unit is disposed above the top surface between the gate electrode and the drain electrode, and the field plate unit has a profile that changes along the X direction.

### BACKGROUND

The development trend of power devices (e.g., gallium nitride power devices) focuses on improving efficiency, reducing switching losses, and enhancing thermal management. Many researches focus on enhancing the process stability and cost-effectiveness of these technologies, as well as expanding the applications of power devices in high-performance power supplies and electric vehicles.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 67 are schematic views illustrating intermediate stages of the method for manufacturing the semiconductor structure in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The present disclosure is directed to a method for manufacturing a semiconductor device. In forming the semiconductor structure, after a channel layer is formed on a substrate, a barrier layer is formed on the channel layer opposite to the substrate. The barrier layer has a top surface opposite to the channel layer. The top surface extends along an X direction. Next, a barrier unit is formed on the top surface. The barrier unit has a content of a Group III element changing along the X direction. Then, a source electrode and a drain electrode are formed on the top surface of the barrier layer. The source electrode and the drain electrode are disposed at two opposite sides of the barrier unit in the X direction. Subsequently, a gate electrode is formed on the top surface of the barrier layer between the source electrode and the barrier unit. Thereafter, a field plate unit is formed above the top surface between the gate electrode and the drain electrode. The field plate unit has a profile changing along the X direction. The barrier unit and the field plate unit of the semiconductor device may redistribute a surface electric field between the gate electrode and the source electrode. As such, the semiconductor device may achieve a desired reduced surface field behavior (e.g., a surface electric field distribution in a gradient profile), and exhibit superior electric characteristics (e.g., a large breakdown voltage).

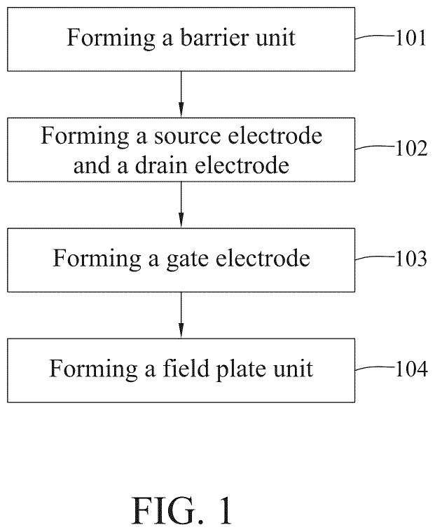

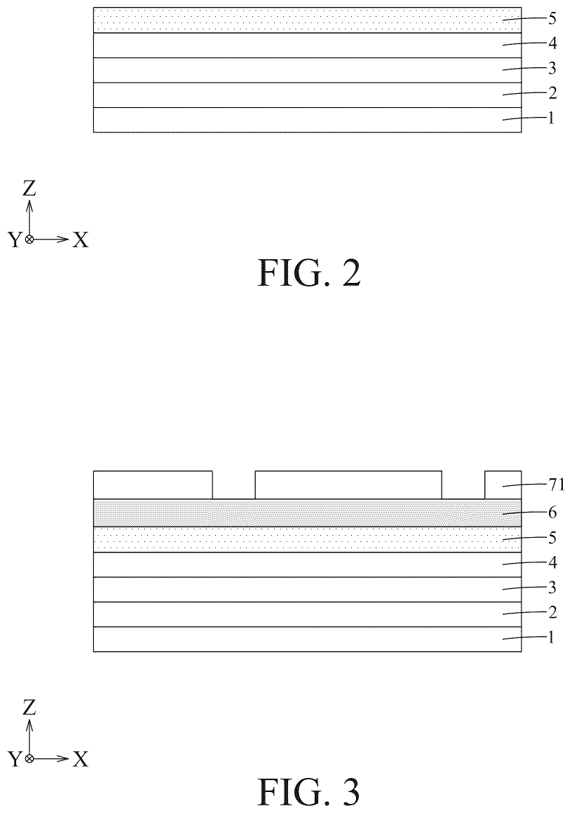

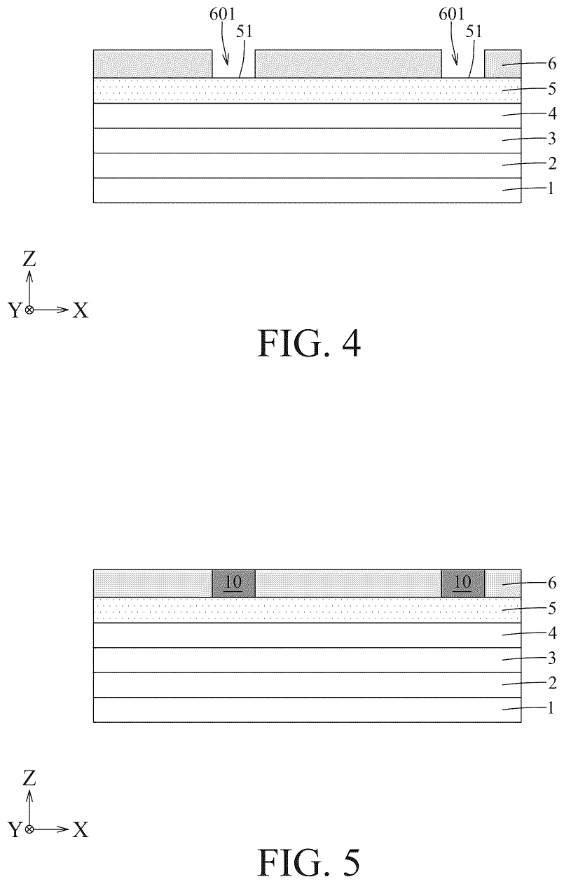

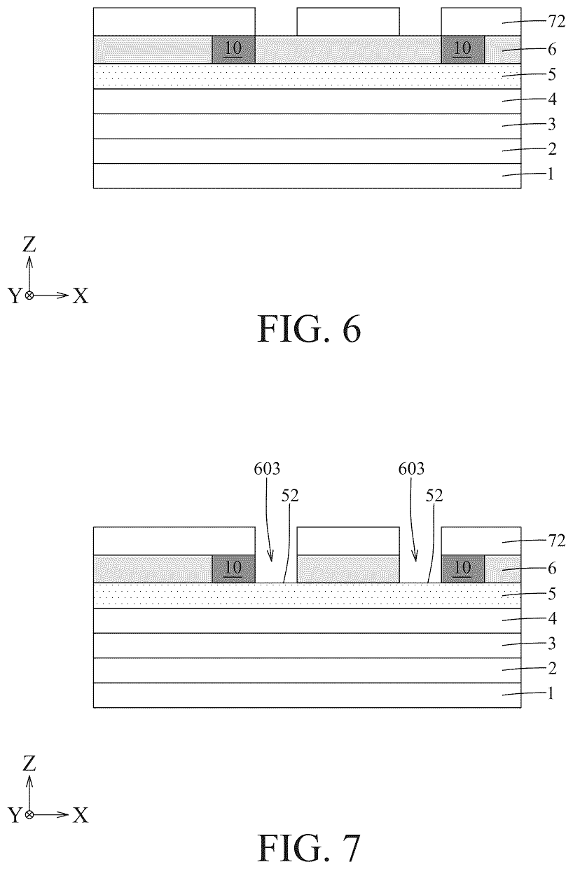

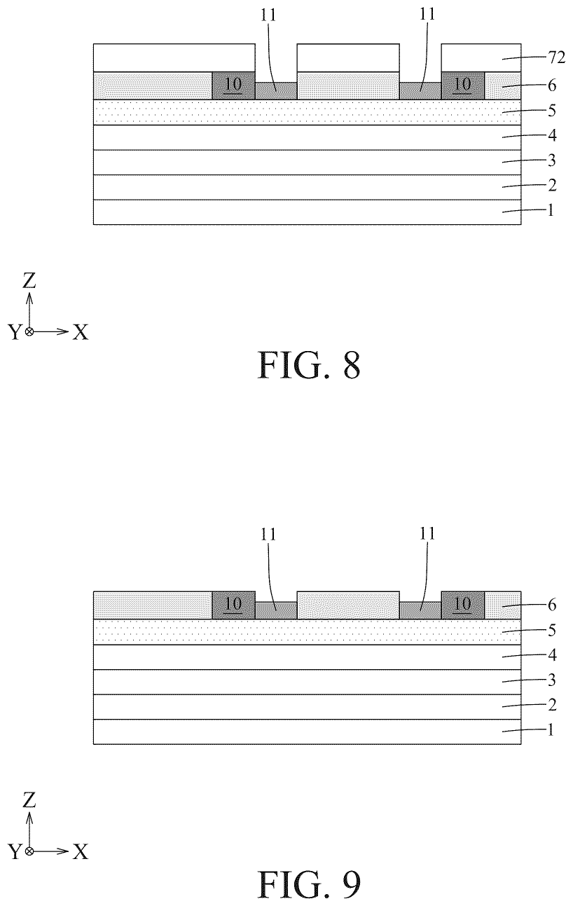

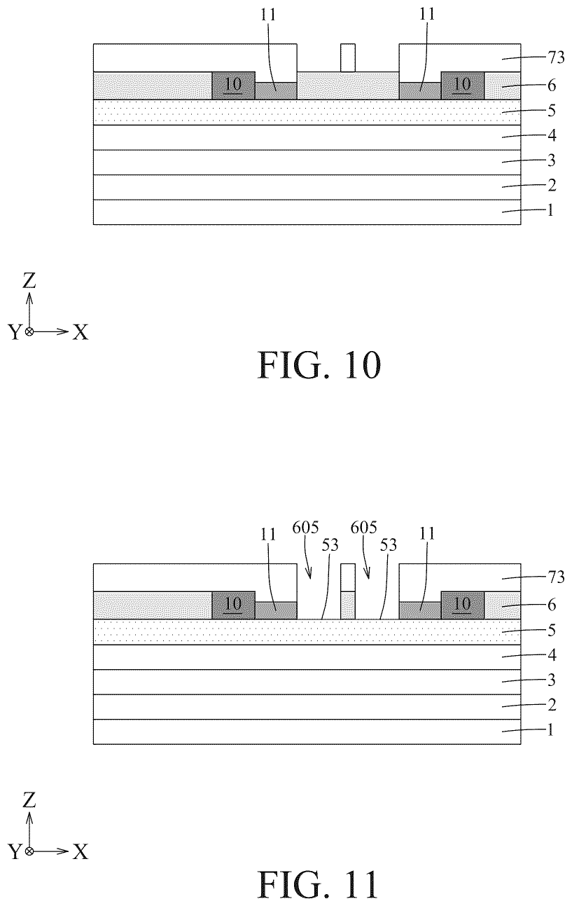

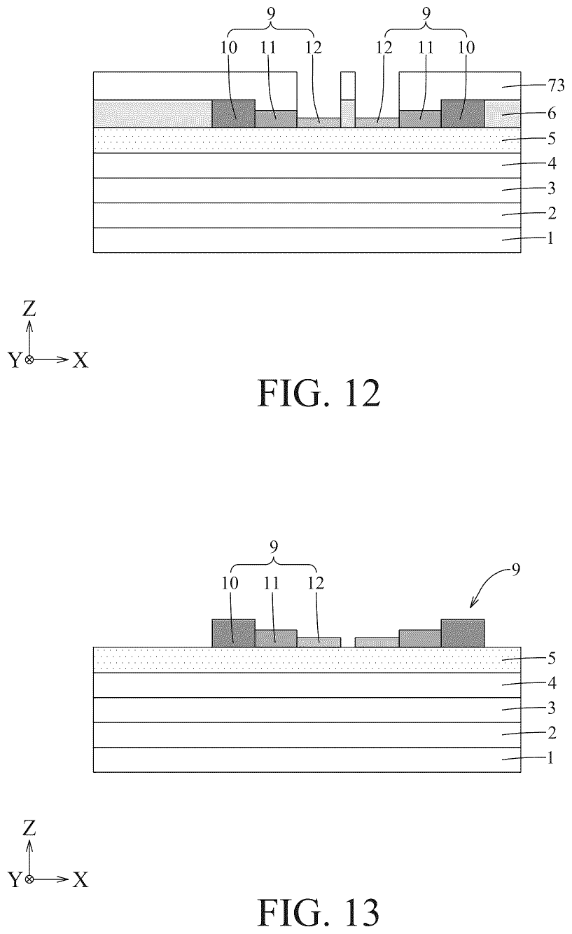

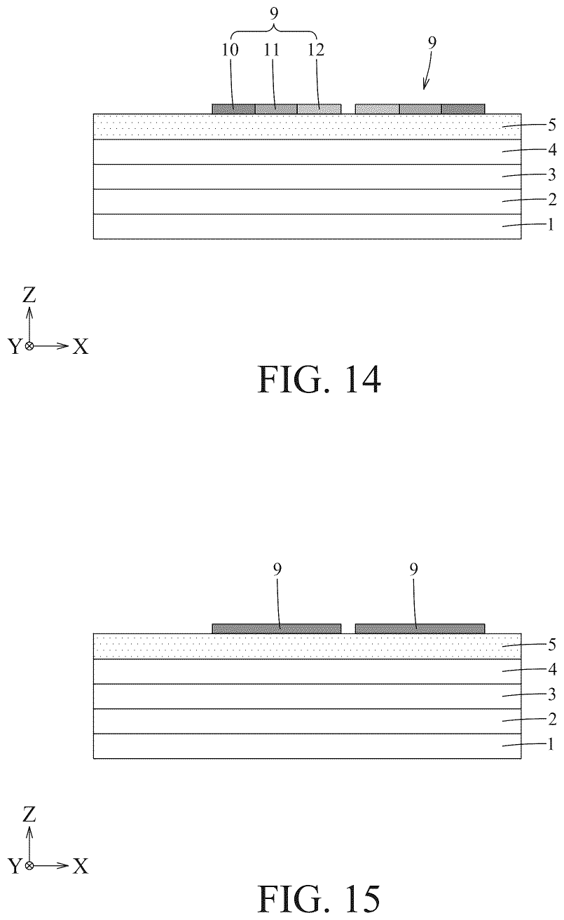

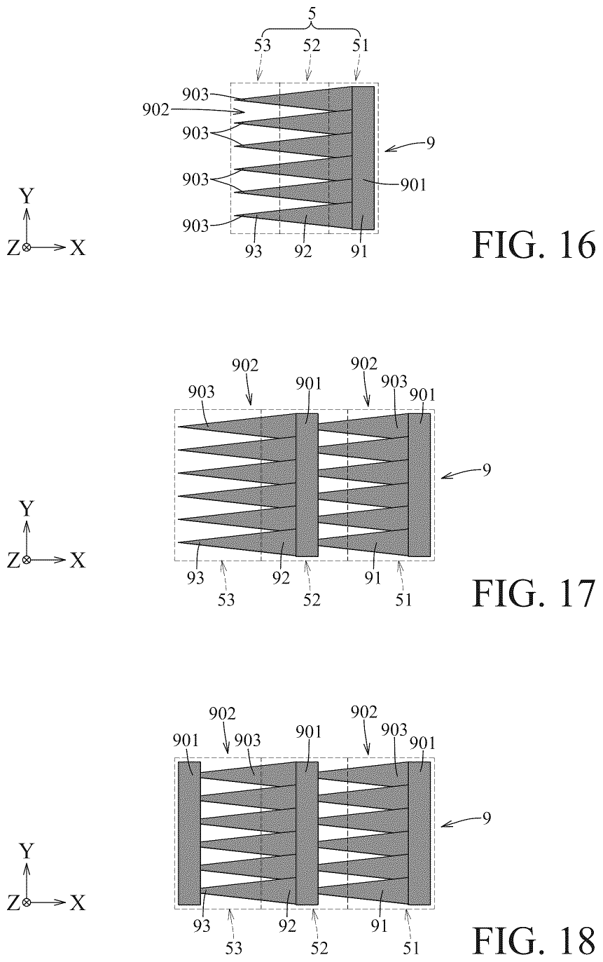

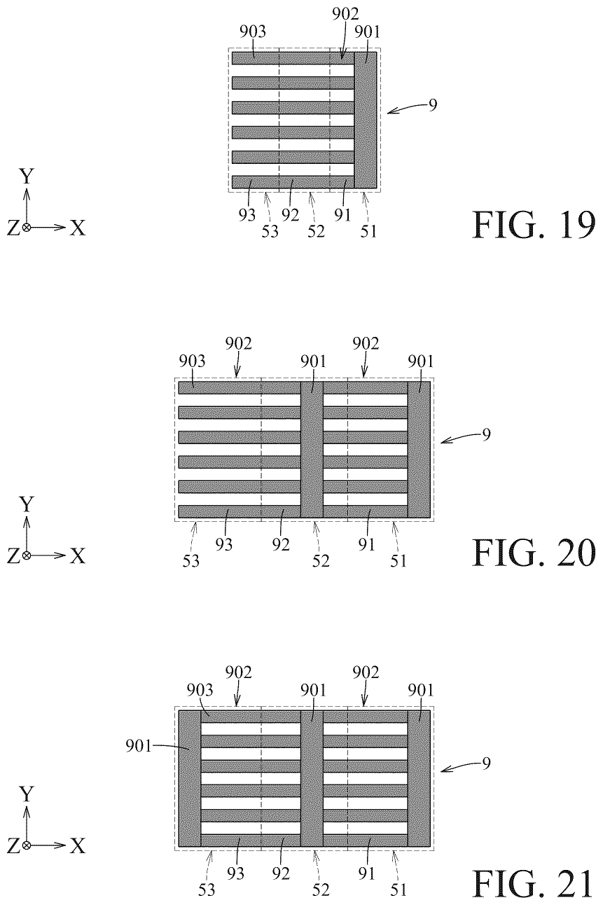

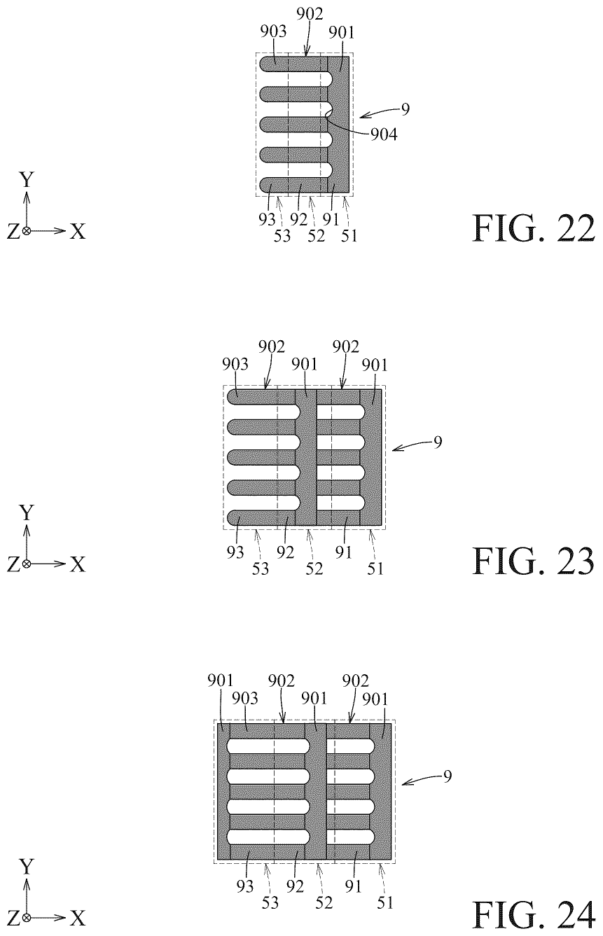

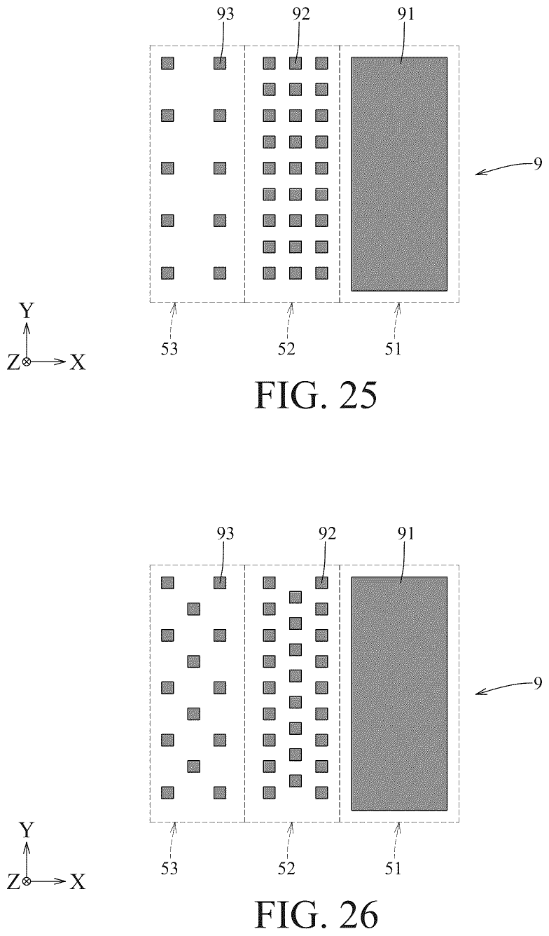

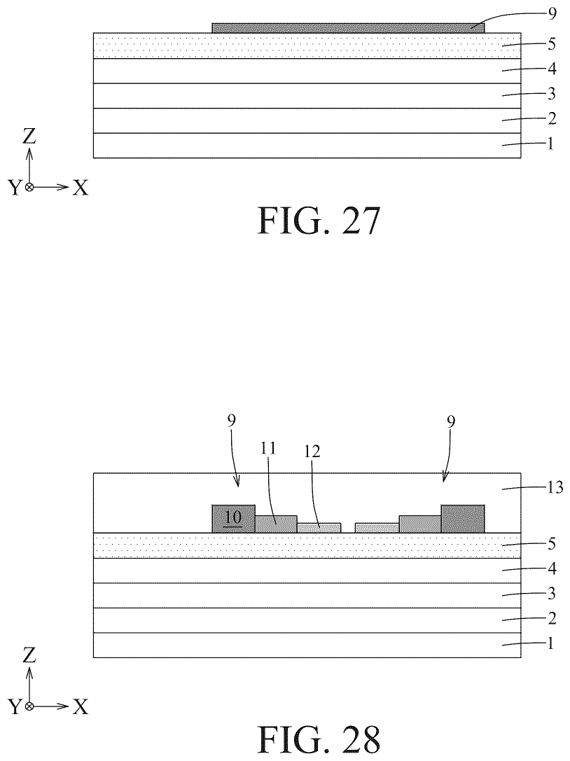

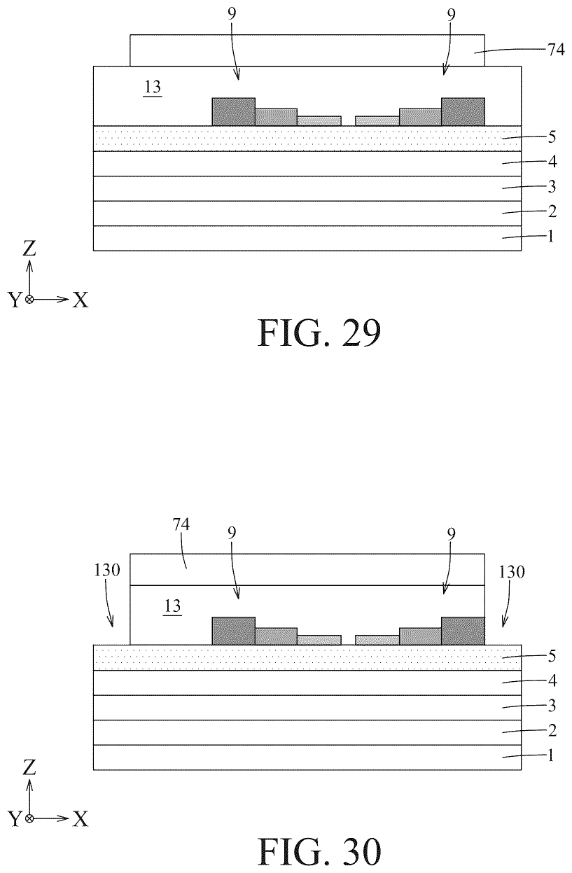

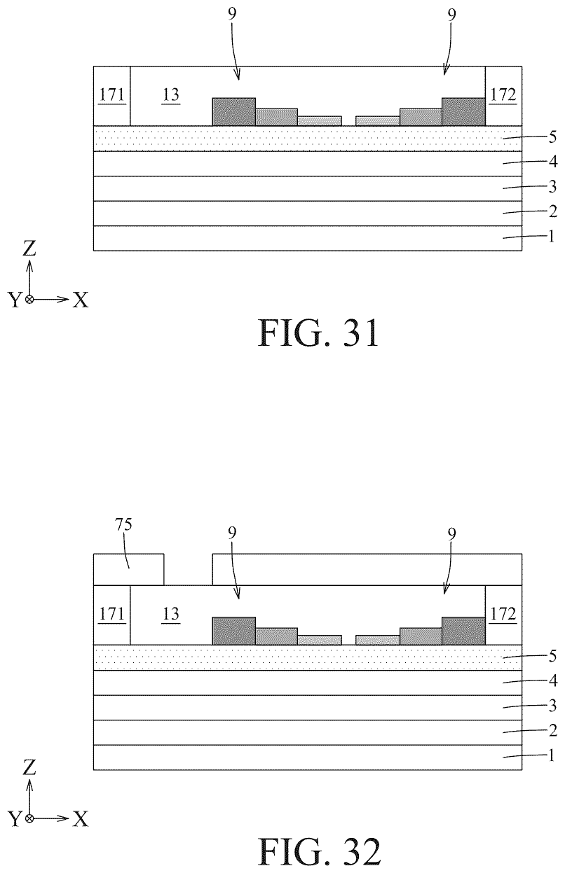

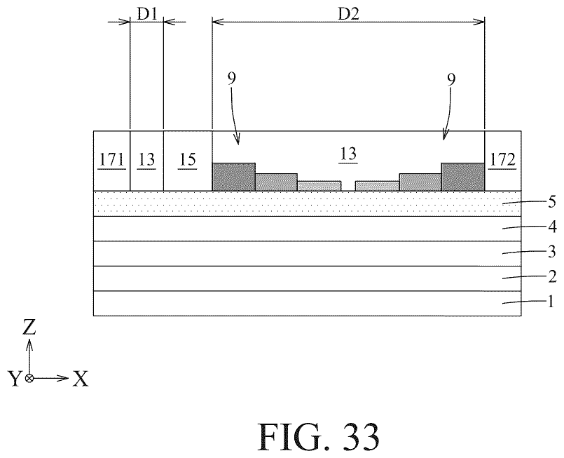

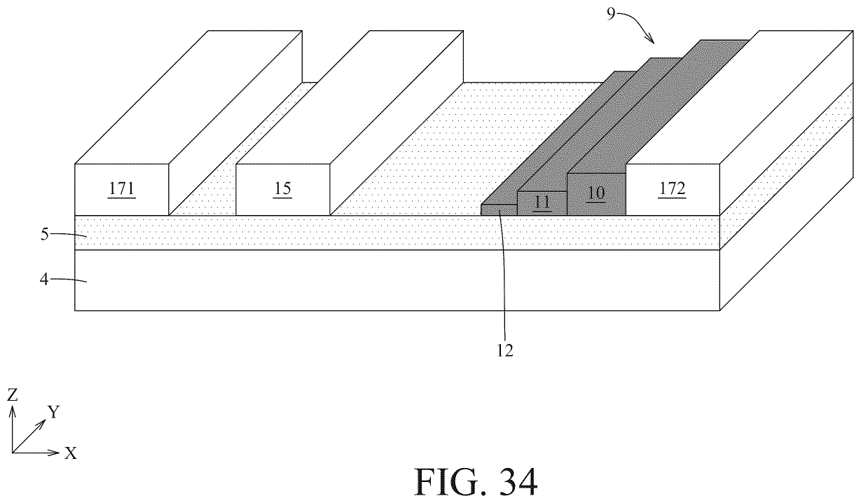

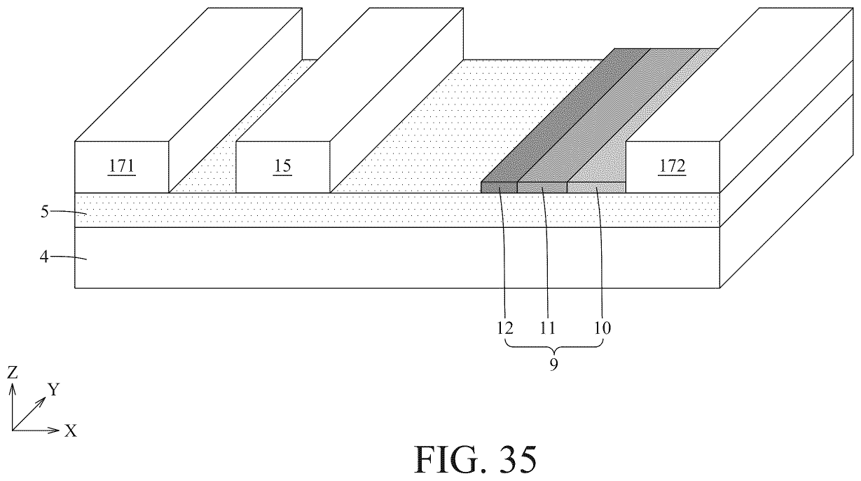

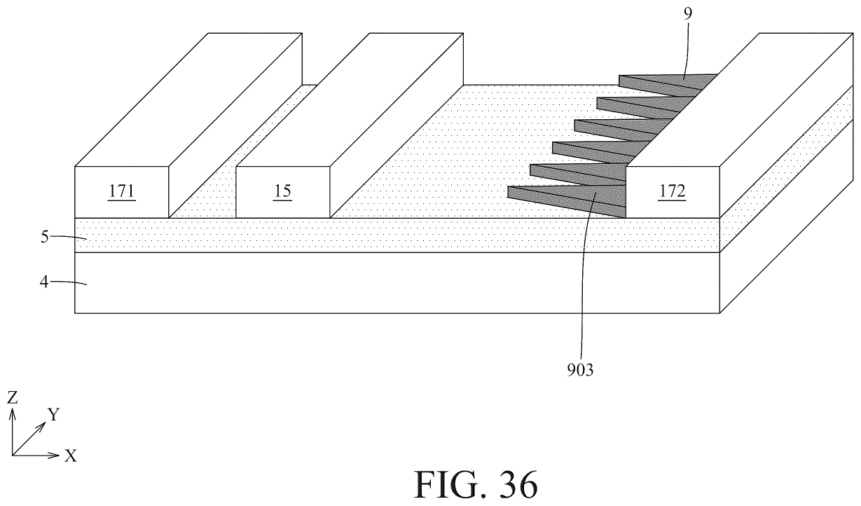

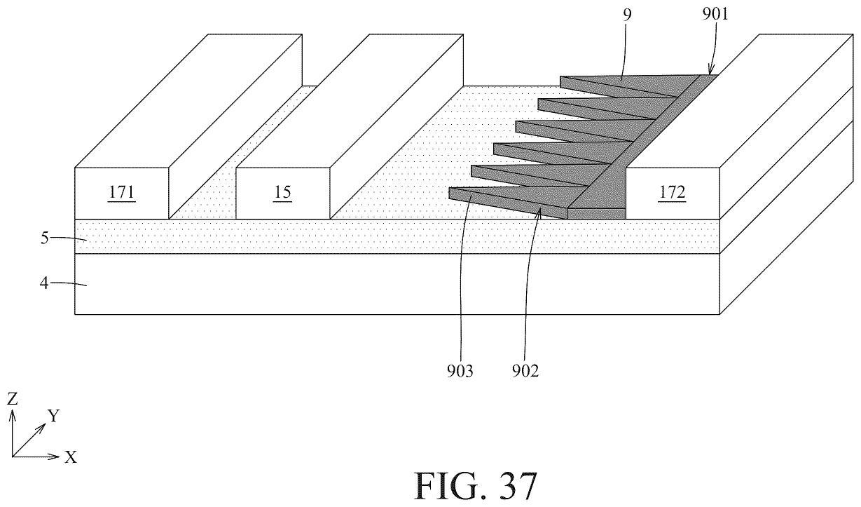

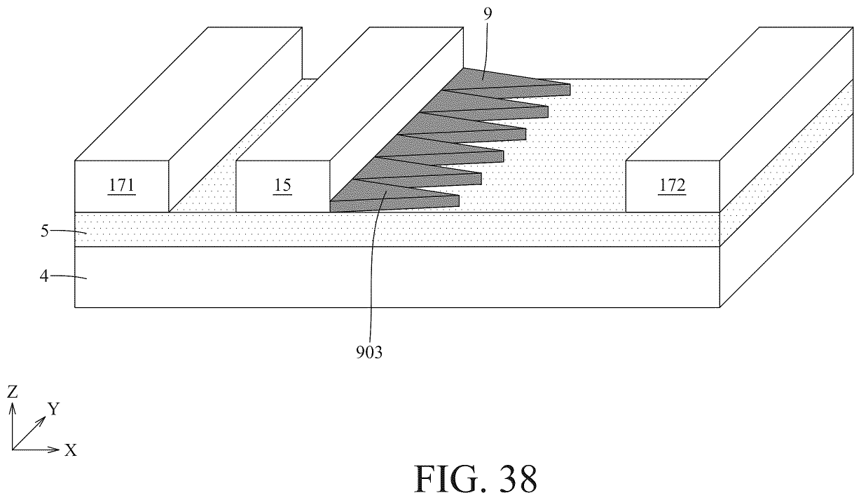

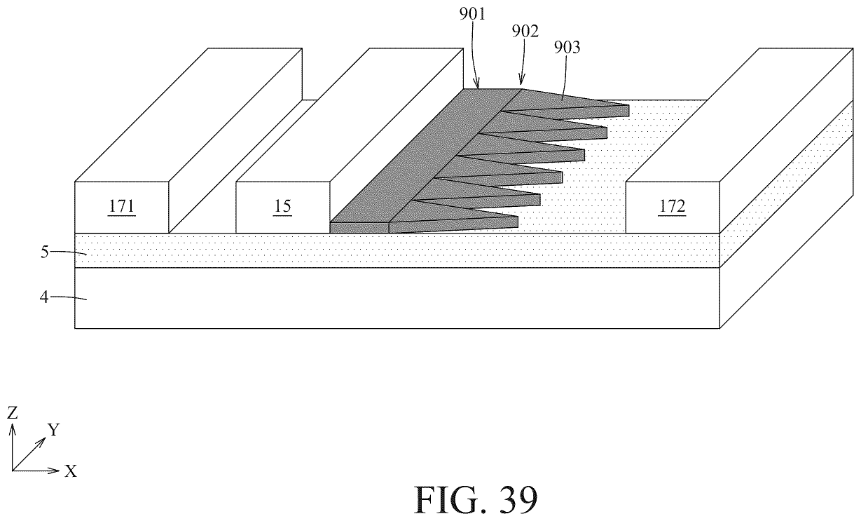

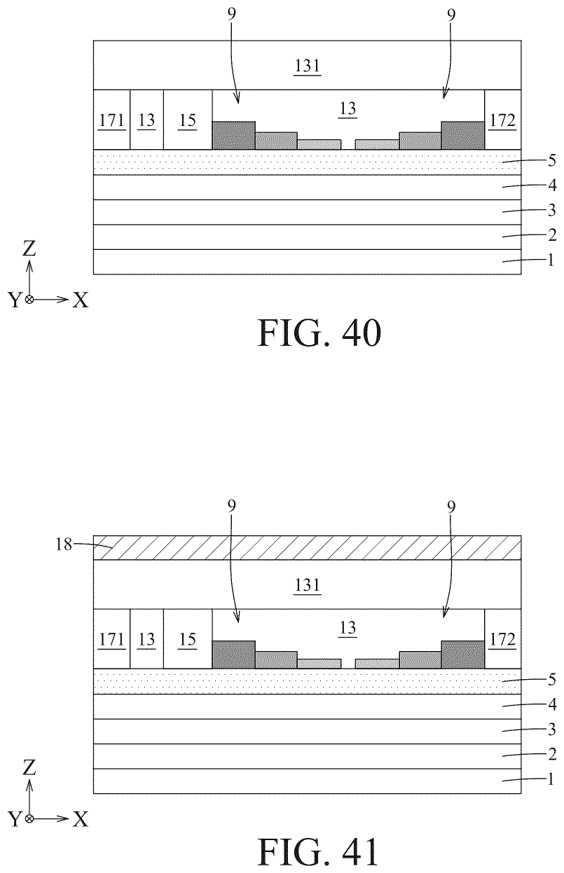

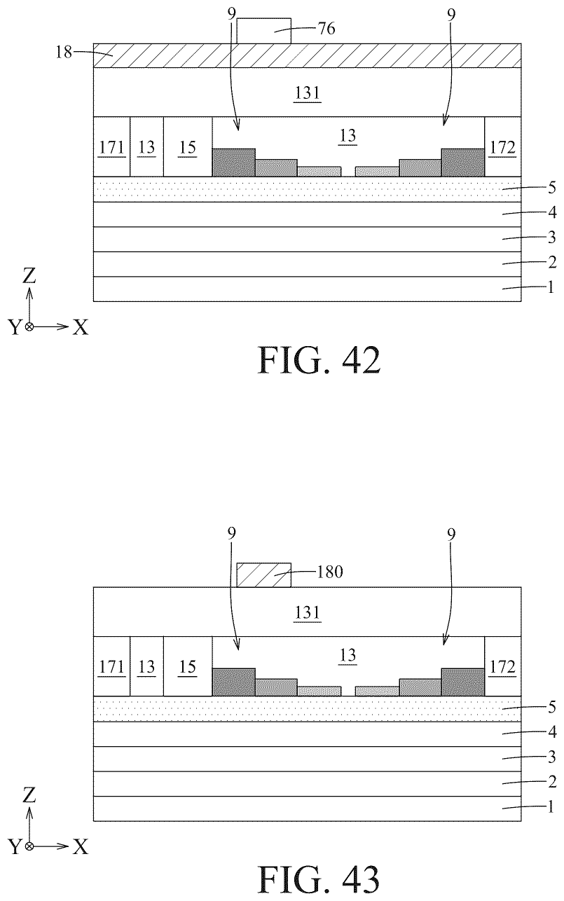

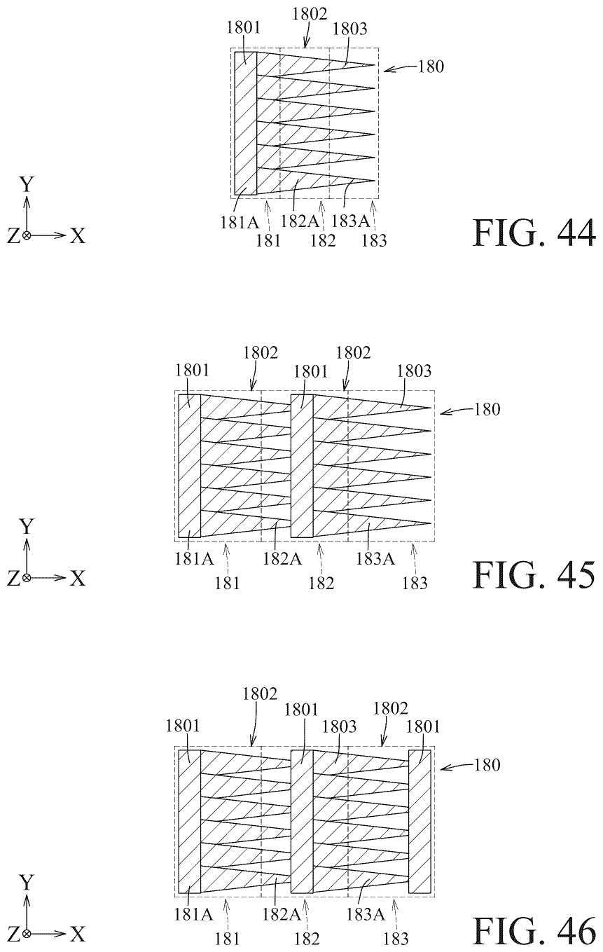

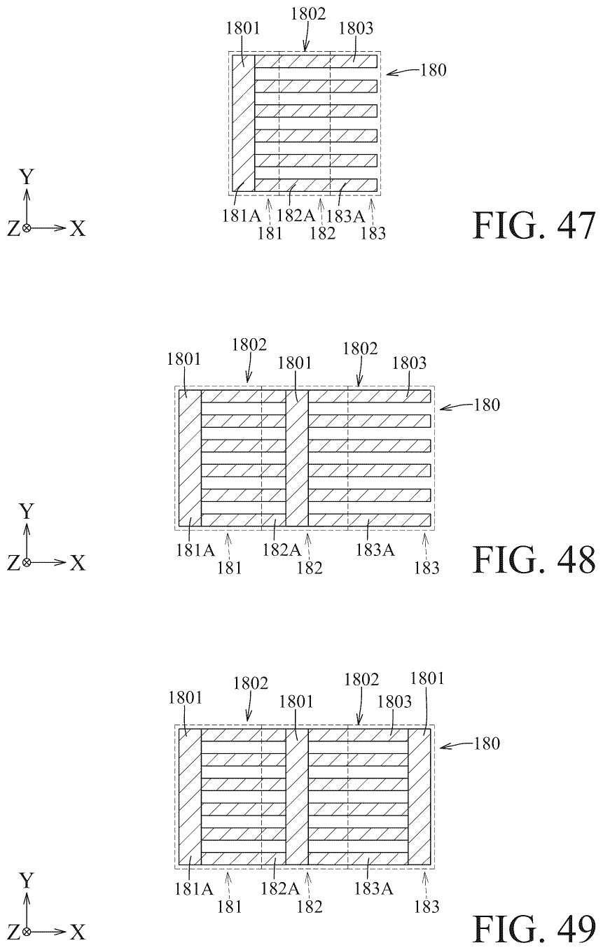

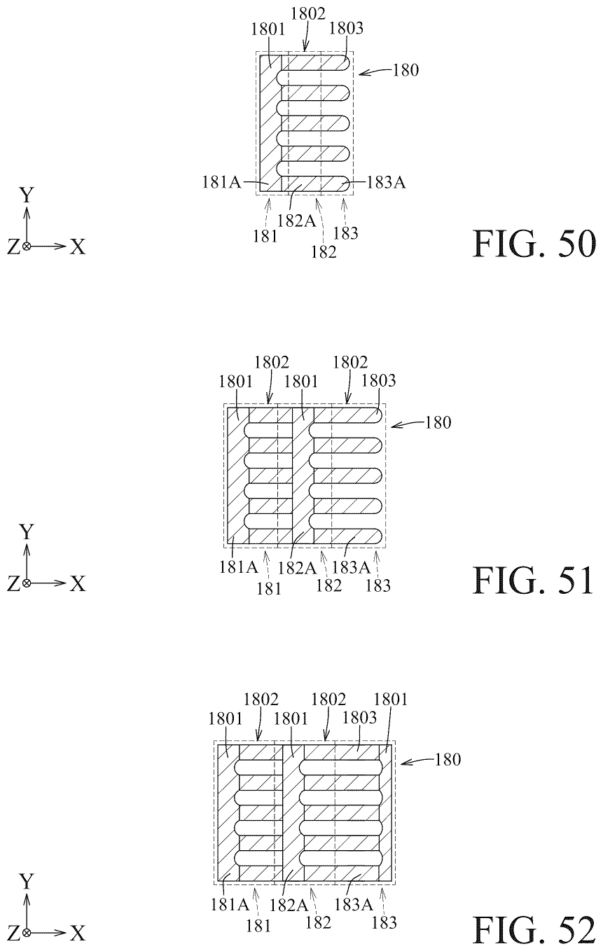

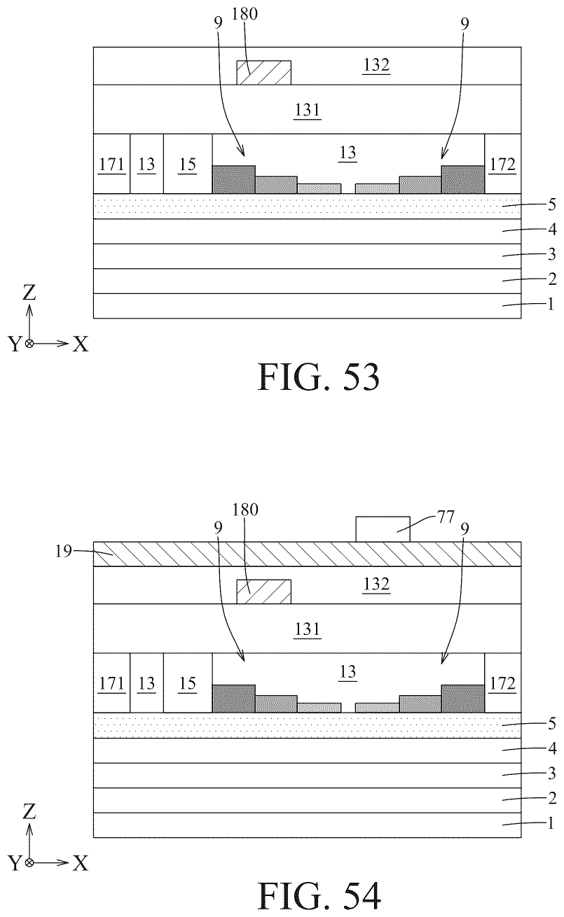

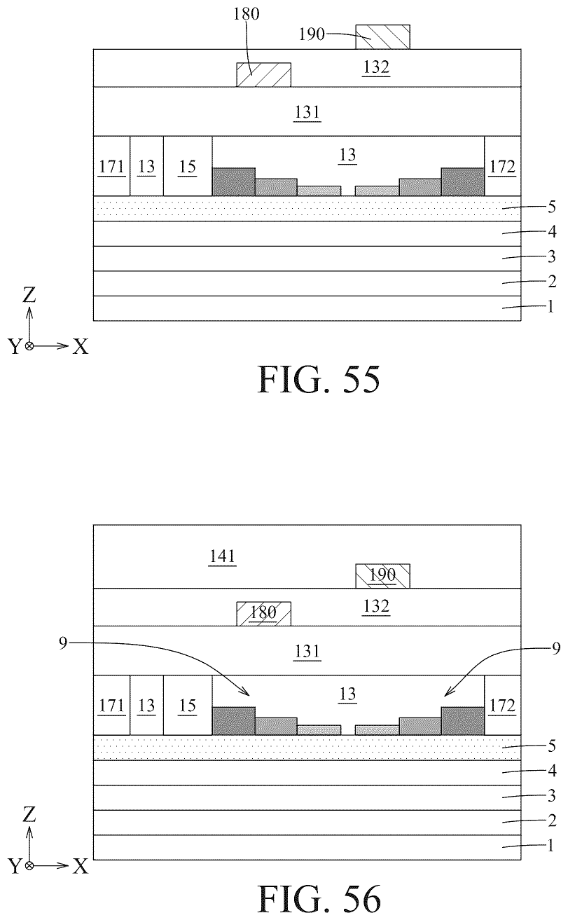

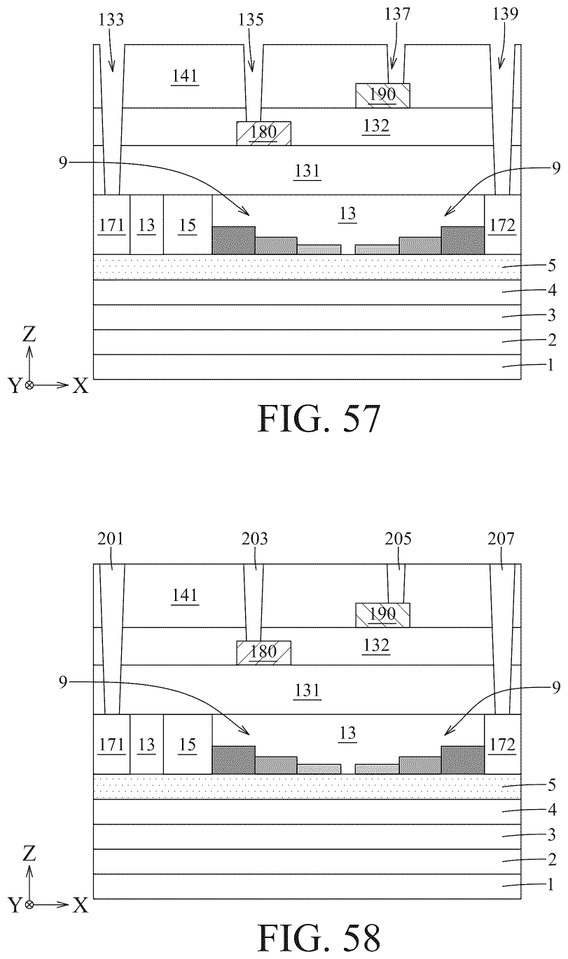

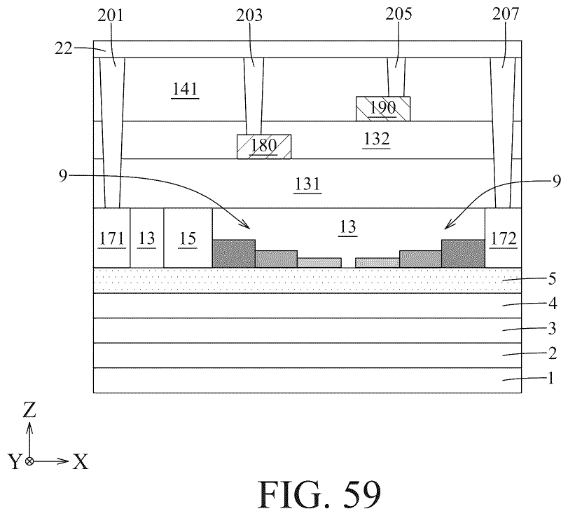

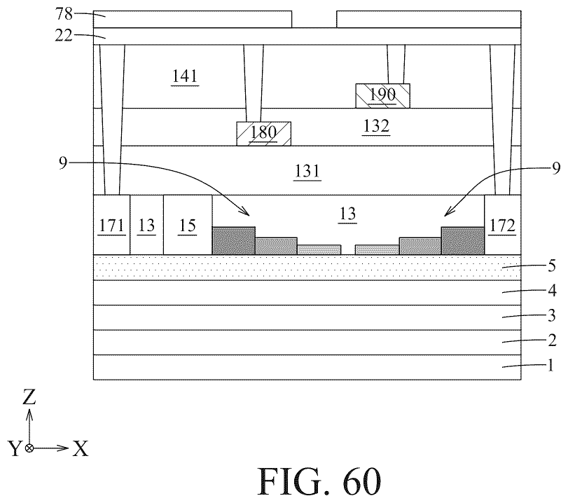

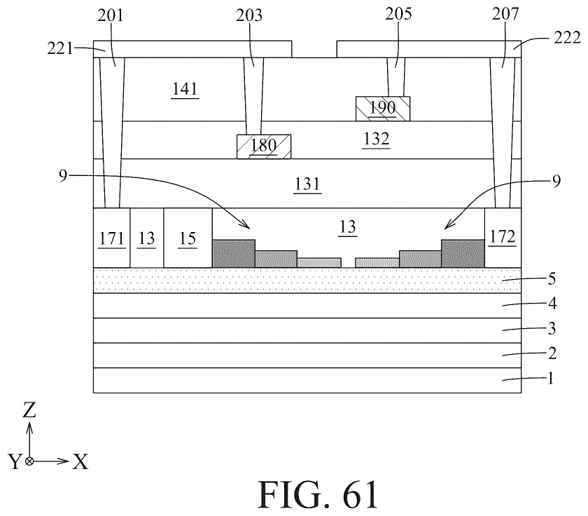

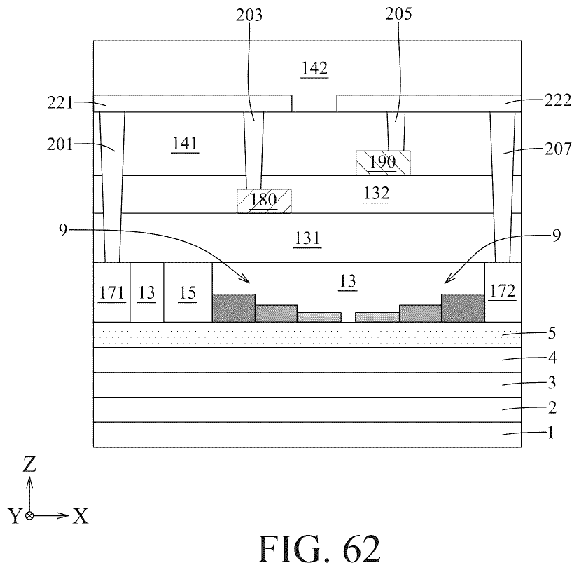

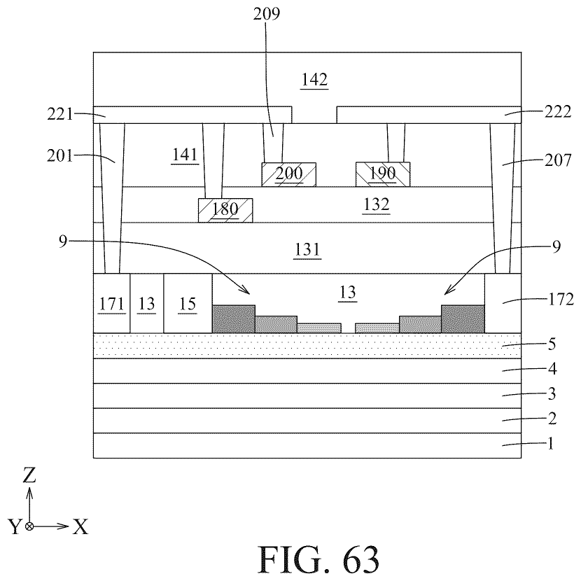

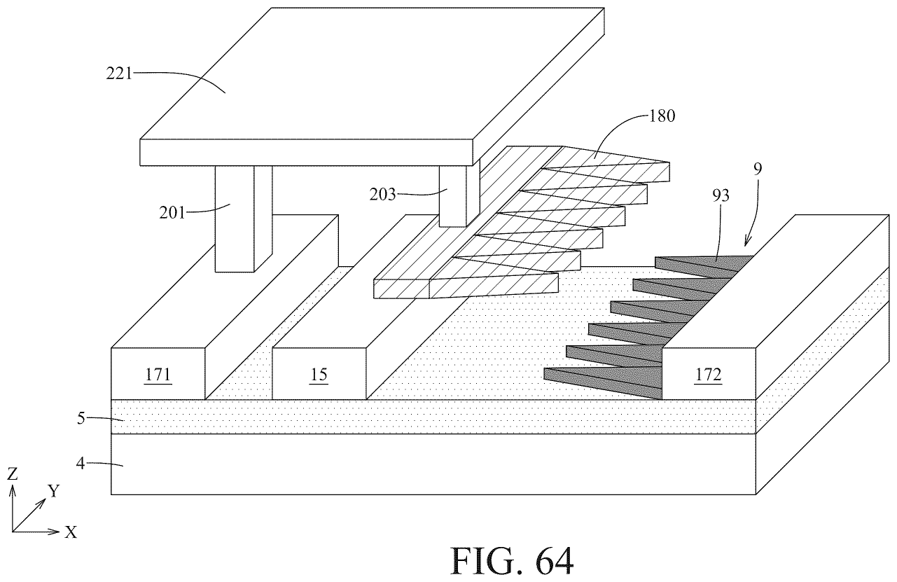

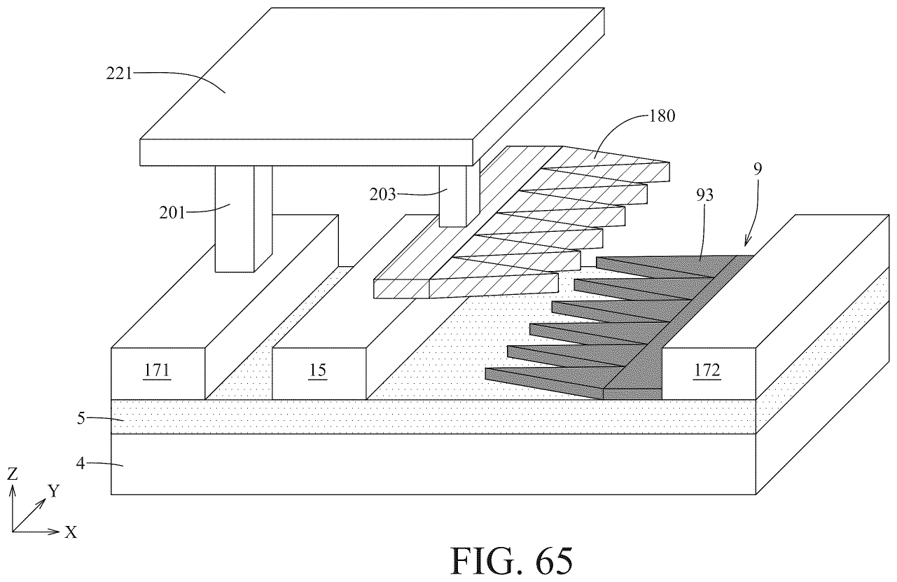

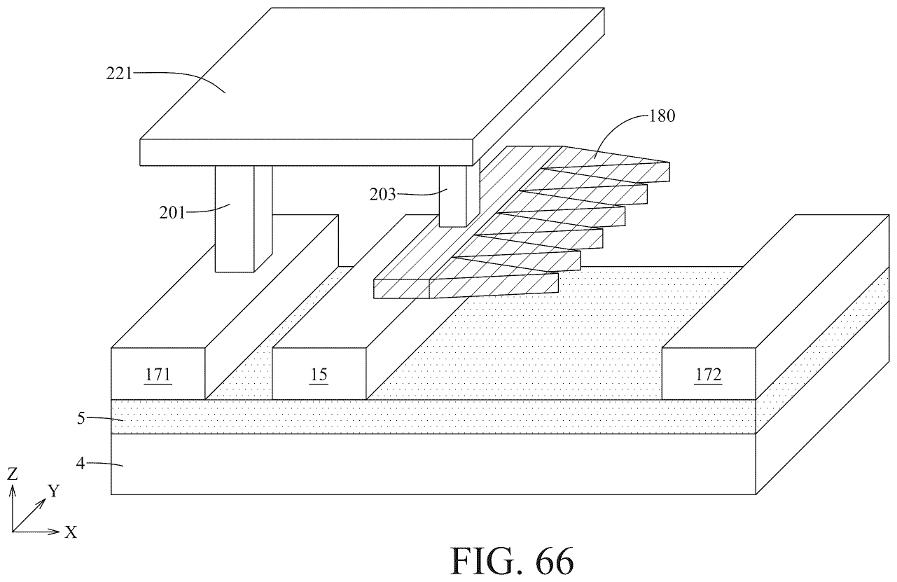

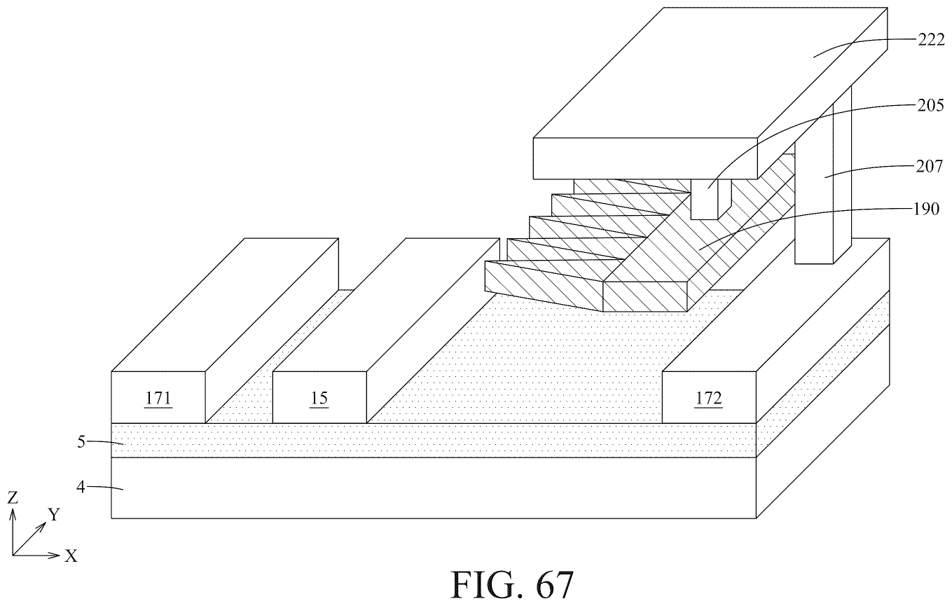

FIG. 1 is a flow diagram illustrating a method for manufacturing the semiconductor structure, for example, the semiconductor structures shown in FIGS. 62 to 67, in accordance with some embodiments. FIGS. 2 to 67 illustrate schematic views of intermediate stages of the method in accordance with some embodiments. Some repeating structures are omitted in FIGS. 2 to 67 for the sake of brevity. Steps illustrated in FIGS. 2 to 67 are also illustrated schematically in the flow diagram shown in FIG. 1. Additional steps can be provided before, after or during the method, and some of the steps described herein may be replaced by other steps or be eliminated.

Referring to FIG. 2, a buffer layer 2, a channel layer 3, an insertion layer 4, and a barrier layer 5 are sequentially formed on a substrate 1 along a Z direction.

A material of the substrate 1 may be determined according to practical needs. In some embodiments, the substrate 1 is a silicon substrate. In certain embodiments, the substrate 1 is a silicon carbide substrate. In other embodiments, the substrate 1 is a sapphire substrate. Other suitable materials for forming the substrate 1 are within the contemplated scope of the present disclosure.

In some embodiments, each of the buffer layer 2, the channel layer 3, the insertion layer 4 and the barrier layer 5 is formed using any suitable process, such as an epitaxy growing process (e.g., hydride vapor phase epitaxy (HVPE), atomic layer epitaxy (ALE)), a deposition process (e.g., chemical vapor deposition (CVD), metal-organic CVD (MOCVD), atomic layer deposition (ALD), physical vapor deposition (PVD)), an ingot pulling process (e.g., a Czochralski process), or other suitable processes, or combinations thereof. The buffer layer 2, the channel layer 3, the insertion layer 4 and the barrier layer 5 may be formed using the same or different processes.

In some embodiments, the buffer layer 2 includes or is made of aluminum nitride, aluminum gallium nitride, gallium nitride, or other suitable materials, or combinations thereof. The buffer layer 2 is configured to adjust stress, and to compensate for lattice mismatch between the substrate 1 and the channel layer 3.

In some embodiments, the channel layer 3 is made of a first III-V compound such as gallium nitride (GaN), gallium arsenide (GaAs), indium phosphide (InP), or other suitable materials, or combinations thereof. In some embodiments, the channel layer 3 is an undoped or unintentionally doped GaN layer.

In some embodiments, the insertion layer 4 includes or is made of aluminum nitride. In some embodiments, the insertion layer 4 may be omitted according to practical needs.

The barrier layer 5 has a top surface that is opposite to the channel layer 3 and that extends along an X direction different from the Z direction. In some embodiments, a barrier unit 9 (see FIG. 27) is subsequently formed on the barrier layer 5. In some other embodiments, multiple barrier units 9 (see FIGS. 13 to 15) are formed on the barrier layer 5. The top surface of the barrier layer 5 has one or multiple portions for forming one or multiple barrier units 9 thereon. Each of the portions of the top surface of the barrier layer 5 is divided into regions (e.g., 51, 52, 53 shown in FIGS. 4, 7, 11, or shown in FIGS. 16 to 26) and the regions 51 to 53 are displaced from each other in the X direction. In some embodiments, the regions 51 to 53 are of equal size.

In some embodiments, the barrier layer 5 includes or is made of a second III-V compound, such as aluminum gallium nitride (AlGaN), indium aluminum nitride (InAIN), aluminum nitride (AlN), aluminum gallium arsenide (AlGaAs), aluminum indium arsenide (InAlAs), indium gallium arsenide (InGaAs), or other suitable materials, or combinations thereof. The second III-V compound is different from the first III-V compound.

Referring to FIG. 3, a dielectric layer 6 is formed over the barrier layer 5, and a first patterned mask 71 is formed over the dielectric layer 6 in a way that partially exposes the dielectric layer 6.

In some embodiments, the dielectric layer 6 is formed over the barrier layer 5 using one or more suitable deposition processes (e.g., atmosphere pressure CVD (APCVD), low pressure CVD (LPCVD), plasma enhanced CVD (PECVD), ALD, or combinations thereof), or other suitable processes. In some embodiments, the patterned mask 71 is a patterned hard mask layer. The patterned hard mask may be formed by forming a hard mask layer (not shown) for forming the patterned mask 71 over the dielectric layer 6, and performing a patterning process to form the hard mask layer into the patterned hard mask layer. In some embodiments, the patterning process may include a photolithography process followed by an etching process, or other suitable processes. The photolithography process may include: forming a photoresist layer over a structure to be patterned by, e.g., spin coating; and patterning the photoresist layer using a photomask or without a mask (e.g., ion-beam writing). The etching process, which utilizes the patterned photoresist layer as an etching mask, may include etching the structure to be patterned by, for example, dry etching, wet etching, or a combination thereof. In some embodiments, the patterned mask 71 is the patterned photoresist layer formed using the photolithography process, and in such case, the hard mask layer and the etching process for forming the hard mask layer into the patterned hard mask layer may be omitted. In the following description, a patterning process, a photolithography process and/or an etching process, unless otherwise stated or defined in this disclosure, may be performed in a way similar to the above-mentioned ones.

In some embodiments, the dielectric layer 6 includes or is made of silicon oxide, aluminum oxide, hafnium oxide, titanium oxide, zirconium oxide, silicon nitride, silicon carbide, silicon oxynitride, silicon oxycarbide, silicon oxycarbonitride, other suitable materials, or combinations thereof.

In some embodiments, the patterned mask 71 may be a single layer structure, or a multi-layered structure. The patterned mask 71 may include or may be made of a dielectric material, such as silicon nitride, silicon oxide, silicon oxynitride, or combinations thereof. In some other embodiments, the patterned mask 71 is made of any suitable material for forming the photoresist layer. In the following description, unless otherwise stated or defined in this disclosure, processes and materials for forming other patterned masks may be similar to those for forming the patterned mask 71, and are not repeated for the sake of brevity.

Referring to FIG. 4, portions of the dielectric layer 6 (exposed from the patterned mask 71, see FIG. 3) are removed to form openings 601, and regions 51 of the barrier layer 5 are exposed through the openings 601, respectively. Then, the patterned mask 71 is removed. Each of the openings 601 is elongated in a Y direction different from both the X and Z directions. In some embodiments, the X, Y and Z directions are perpendicular to one another. In some embodiments, as shown in FIG. 4, two openings 601 are formed, but the number of the openings 601 is not so limited and may be one or more than two based on the number of the barrier unit(s) 9 (e.g., see FIG. 13) to be formed. Other suitable numbers of and/or configurations for the openings 601 are within the contemplated scope of the present disclosure.

In some embodiments, the openings 601 are formed in the dielectric layer 6 by an etching process using the patterned mask 71 as an etching mask. In some embodiments, the etching process may include a dry etching process (e.g., a plasma etching process, a reactive ion etching process, or other suitable processes), a wet etching process, other suitable processes, or combinations thereof. Thereafter, the patterned mask 71 is removed by any suitable process (e.g., an ashing process, a wet etching process, a dry etching process, or combinations thereof).

Referring to FIG. 5, barrier parts 10 are formed respectively in the openings 601 to cover the regions 51 of the barrier layer 5 (see FIG. 4). In some embodiments, the barrier parts 10 and the dielectric layer 6 are substantially coplanar.

In some embodiments, in forming the barrier parts 10, a barrier material (not shown, for forming the barrier parts 10) is deposited over the structure shown in FIG. 4 by any suitable process (e.g., HVPE, ALE, CVD, MOCVD, ALD, PVD, or combinations thereof) to fill the openings 601. Then, an excess amount of the barrier material is removed by a planarization process (e.g., chemical mechanical planarization (CMP)) to expose the dielectric layer 6. The barrier material may include a third III-V compound, which may be the same or different from the second III-V compound for forming the barrier layer 5. Possible materials for the third III-V compound are similar to those of the second III-V compound, and thus details thereof are omitted for the sake of brevity.

Referring to FIG. 6, a patterned mask 72 is formed over the barrier parts 10 and the remaining dielectric layer 6 in a way that partially exposes the remaining dielectric layer 6.

Referring to FIG. 7, portions of the remaining dielectric layer 6 (exposed from the patterned mask 72, see FIG. 6) are removed to form openings 603, and regions 52 of the barrier layer 5 are exposed through the openings 603, respectively. In some embodiments, each of the barrier parts 10 is exposed to a corresponding one of the openings 603. Possible processes for forming the openings 603 are similar to those for forming the openings 601, and thus details thereof are omitted for the sake of brevity.

Referring to FIG. 8, barrier parts 11 are formed respectively in the openings 603 to cover the regions 52 of the barrier layer 5 (see FIG. 7). In some embodiments, a thickness in the Z direction of each of the barrier parts 11 is less than a thickness in the Z direction of a corresponding adjacent one of the barrier parts 10. In some other embodiments not shown, the thickness in the Z direction of each of the barrier parts 11 is larger than the thickness in the Z direction of the corresponding adjacent barrier part In some embodiments, in forming the barrier parts 11, a barrier material (not shown, for forming the barrier parts 11) is deposited over the structure shown in FIG. 7 by any suitable deposition process (e.g., HVPE, ALE, CVD, MOCVD, ALD, PVD, or combinations thereof) to fill the openings 603. Next, a planarization process (e.g., CMP, or other suitable processes) is performed to remove the barrier material on the patterned mask 72 and to expose the patterned mask 72. Thereafter, an etching back process (e.g., plasma etching process, reactive ion etching process, or other suitable processes) is performed to etch back the remaining barrier material, thereby obtaining the barrier parts 11.

Possible materials for the barrier parts 11 are similar to those of the barrier parts 10, and thus details thereof are omitted for the sake of brevity. The barrier parts 10 and the barrier parts 11 may be made of the same or different materials.

Referring to FIG. 9, the patterned mask 72 shown in FIG. 8 is removed in a manner similar to that of removing the patterned mask 71.

Referring to FIG. 10, a patterned mask 73 is formed over the barrier parts 10, 11 and the remaining dielectric layer 6 in a way that partially exposes the remaining dielectric layer 6.

Referring to FIG. 11, portions of the remaining dielectric layer 6 (exposed from the patterned mask 73, see FIG. 10) are removed to form openings 605 and regions 53 of the first barrier layer 5 are exposed from the openings 605, respectively. In some embodiments, each of the barrier layers 11 is exposed to a corresponding one of the openings 605. Possible processes for forming the openings 605 are similar to those for forming the openings 601, and thus details thereof are omitted for the sake of brevity.

Referring to FIG. 12, barrier parts 12 are formed respectively in the openings 605 to cover the regions 53 of the barrier layer 5 (see FIG. 11). In some embodiments, each of the barrier parts 12 has a thickness in the Z direction smaller than the thickness in the Z direction of a corresponding adjacent one of the barrier parts 11. In some other embodiments not shown, the thickness in the Z direction of each of the barrier parts 12 is larger than the thickness in the Z direction of the corresponding adjacent barrier part 11.

In some embodiments, in forming the barrier parts 12, a barrier material (not shown, for forming the barrier parts 12) is deposited over the structure shown in FIG. 13 by any deposition process (e.g., HVPE, ALE, CVD, MOCVD, ALD, PVD, or combinations thereof), or other suitable processes to fill the openings 605. Next, a planarization process (e.g., CMP, or other suitable processes) is performed to remove the barrier material on the patterned mask 73 and to expose the patterned mask 73. Thereafter, an etching back process (e.g., plasma etching process, reactive ion etching process, or other suitable processes) is performed to etch back the remaining barrier material, thereby obtaining the barrier parts 12.

Possible materials for the barrier parts 12 are similar to those of the barrier parts 10 and/or 11, and thus the details thereof are omitted for the sake of brevity. The barrier parts 10, 11, and 12 may be made of the same or different materials.

Referring to FIG. 13, the patterned mask 73 and the remaining dielectric layer 6 shown in FIG. 12 are removed to expose the barrier layer 5. Possible processes for removing the patterned mask 73 are similar to those for removing the patterned mask 71, and thus details thereof are omitted for the sake brevity. In some embodiments, the remaining dielectric layer 6 is removed by any suitable etching process (e.g., a wet etching process, a dry etching process, or a combination thereof).

As such, barrier units 9 are formed on the top surface of the barrier layer 5. In the exemplary embodiment shown in FIG. 13, there are two of the barrier units 9, each of which includes one of the barrier parts 10, an adjacent corresponding one of the barrier parts 11, and an adjacent corresponding one of the barrier parts 12. In some embodiments, the barrier units 9 are arranged opposite to each other in the X direction. In some embodiments, each of the barrier units 9 has a staircase-shaped structure. It should be noted that (i) the number of the barrier unit(s) 9, (ii) the number of the barrier parts in each of the barrier unit(s) 9, (iii) configuration(s) of the barrier unit(s) 9, and (iv) configuration(s) of the barrier parts in each of the barrier unit(s) 9 are not limited to those illustrated in FIG. 13. Other suitable numbers and/or configurations of the barrier units 9 and the barrier parts in each of the barrier units 9 are within the contemplated scope of the present disclosure. In some embodiments, the barrier parts 10, 11, 12 are made of different III-V compounds (the III-V compounds for forming the barrier parts 10, 11, 12 are collectively referred to as the third III-V compound). In some embodiments, the barrier parts 10, 11, 12 are made of the same third III-V compound, and in such case, because the barrier parts 10, 11, 12 are displaced from each other in the X direction and have different thicknesses, a content of the Group III element (i.e., amount of atoms of the Group III element) in each of the barrier units 9 may change along the X direction.

To be exact, in the present disclosure, each of the barrier units 9 includes the third III-V compound, in which the content of the Group III element changes along the X direction. That is, in each of the barrier units 9, the amount of the Group III element atoms changes along the X direction. FIGS. 14 to 27 demonstrate further variant structures of the barrier unit(s) 9 in accordance with some embodiments.

FIG. 14 shows a variant structure of the barrier units 9 in accordance with some embodiments. The barrier units 9 shown in FIG. 14 are similar to those shown in FIG. 13, except that the barrier parts 10, 11, 12 in each of the barrier units 9 have substantially the same thickness. The barrier parts 10, 11, 12 shown in FIG. 14, may each be formed in a manner similar to that for forming the barrier parts 10 described with reference to FIGS. 3 to 5. In some embodiments, the barrier parts 10, 11, 12 are made of the third III-V compound but concentrations of the Group III element in the barrier parts 10, 11, 12 are different from each other. In such case, because the barrier parts 10, 11, 12 are displaced from each other in the X direction and have substantially the same thickness, a content of the Group III element (i.e., an amount of atoms of the Group III element) in each of the barrier units 9 changes along the X direction. For example, in each of the barrier units 9, the concentration of the Group III element in the barrier part 12 is greater than the concentration of the Group III element in the barrier part 11, and the concentration of the Group III element in the barrier part 11 is greater than the concentration of the Group III element in the barrier part 10. In some other embodiments, in each of the barrier units 9, the concentration of the Group III element in the barrier part 12 is less than the concentration of the Group III element in the barrier part 11, and the concentration of the Group III element in the barrier part 11 is less than the concentration of the Group III element in the barrier part 10. In each of the barrier units 9, a concentration difference of the Group III element between two adjacent ones of the barrier parts 10, 11, 12 may range from about 5 atomic percent to about 30 atomic percent (e.g., about 5 atomic percent, about 10 atomic percent, about 15 atomic percent, about 20 atomic percent, about 25 atomic percent, or about 30 atomic percent). For example, in each of the barrier units 9, the concentration of the Group III element (e.g., aluminum) in the barrier part 10 ranges from about 60 atomic percent to about 25 atomic percent based on 100 atomic percent of the third III-V compound (e.g., aluminum gallium nitride) in the barrier part 10, the concentration of the Group III element (e.g., aluminum) in the barrier part 11 ranges from about 50 atomic percent to about 15 atomic percent based on 100 atomic percent of the third III-V compound (e.g., aluminum gallium nitride) in the barrier part 11, and the concentration of the Group III element (e.g., aluminum) in the barrier part 12 ranges from about 40 atomic percent to about 5 atomic percent based on 100 atomic percent of the third III-V compound (e.g., aluminum gallium nitride) in the barrier part 12.

In some embodiments, the third III-V compound is aluminum gallium nitride. In one example, in each of the barrier units 9, an aluminum concentration of the barrier part 10 is greater than an aluminum concentration of the barrier part 11, and the aluminum concentration of the barrier part 11 is greater than an aluminum concentration of the barrier part 12. In some other embodiments not shown, the aluminum concentration of the barrier part 10 is less than the aluminum concentration of the barrier part 11, and the aluminum concentration of the barrier part 11 is less than the aluminum concentration of the barrier part 12.

FIG. 15 shows a variant structure of the barrier units 9 in accordance with some embodiments. The barrier units 9 shown in FIG. 15 are similar to those shown in FIG. 14, except that the barrier units 9 shown in FIG. 15 are formed by a deposition process for depositing a layer for forming the barrier units 9 on the barrier layer 5 shown in FIG. 2, followed by a patterning process. In such case, the barrier units 9 may each have a pattern depending on a patterning mask or a patterned photoresist layer used in the patterning process.

FIGS. 16 to 26 are top views illustrating different patterns for one of the barrier units 9 in accordance with some embodiments. In FIGS. 16 to 26, one of the barrier units 9 is shown by solid lines, and one of the portions of the top surface of the barrier layer 5 for forming the one of the barrier units 9 is shown by dotted lines. In the following descriptions, the barrier units 9, and the portions of the top surface of the barrier layer 5 are each described in singular form for the sake of brevity.

In FIG. 16, the portion of the top surface of the barrier layer 5 (see also FIG. 2) includes regions 51, 52, 53 for forming different barrier parts 91, 92, 93 of the barrier unit 9, respectively. It should be noted that for better explanation for the patterns shown in FIGS. 16 to 26, the barrier unit 9 shown in each of FIGS. 16 to 26 is divided into three barrier parts 91 to 93 respectively formed on three regions 51 to 53, but the barrier unit 9 may be divided into two or more than three barrier parts for being formed on two or more regions on the barrier layer 5. The regions 51 to 53 have the same size (and the same area) and are displaced from each other in the X direction. Each of the barrier parts 91 to 93 is disposed on and covers a corresponding one of the regions 51 to 53. Please note that the number of the regions equals to the number of the barrier parts, and is not limited to three. A projection of each of the barrier parts 91 to 93 on the corresponding one of the regions 51 to 53 has a percentage of coverage out of an area of the corresponding one of the regions 51 to 53. The percentage of coverage of one of the barrier parts 91 to 93 is different from the percentage of coverage of an adjacent one of the barrier parts 91 to 93. In other words, a percentage of coverage of a projection of each of the barrier parts 91 to 93 onto a corresponding one of the regions 51 to 53 over an area of the corresponding one of the regions 51 to 53 is different from a percentage of coverage of a projection of an adjacent one of the barrier parts 91 to 93 onto a corresponding one of the regions 51 to 53 over an area of the corresponding one of the regions 51 to 53. Hereinafter, a percentage of coverage of a certain barrier part (e.g., 91) refers to a percentage of a projection of the certain barrier part (e.g., 91) onto a corresponding one of the regions (e.g., 51) over an area of the corresponding one of the regions (e.g., 51). The barrier unit 9 may be configured as a patterned plate structure. The patterned plated structure includes a base portion 901 and an extending portion 902. The extending portion 902 includes extending strips 903 that are displaced from each other in the Y direction. The extending strips 903 extend from the base portion 901 in the X direction. In some embodiments, each of the extending strips 903 is tapered away from the base portion 901. For instance, each of the extending strips 903 has opposite end portions (i.e., a proximal end portion and a distal end portion) that are respectively proximal to and distal to the base portion 901 in the X direction. The proximal end portion has a width (measured along the Y direction) which is larger than a width of the distal end portion. In addition, the content of the Group III element (i.e., amount of atoms of the Group III element) in the barrier unit 9 changes along the X direction.

In FIG. 17, the barrier unit 9 includes two of the base portions 901 (similar to the base portion 901 shown in FIG. 16) and two of the extending portions 902 (similar to the extending portion 902 shown in FIG. 16). Similarly, the content of the Group III element in the barrier unit 9 changes along the X direction. The percentages of coverage of the barrier parts 91 to 93 are different from each other.

In FIG. 18, the barrier unit 9 is similar to the barrier unit 9 shown in FIG. 17, except that the barrier unit 9 of FIG. 18 includes three of the base portions 901, and two of the extending portions 902. Similarly, the content of the Group III element in the barrier unit 9 changes along the X direction. The percentages of coverage of the barrier parts 91 to 93 are different from each other.

The barrier units 9 of FIGS. 19, 20 and 21 are similar to the barrier units 9 of FIGS. 16, 17 and 18, respectively, except that a shape of the extending strips 903 shown in FIGS. 19 to 21 are different from that shown in FIGS. 16 to 18. For instance, in some embodiments, each of the extending strips 903 may have a substantially rectangular shape with a fixed width (measured in the Y direction) along the X direction. For each of the extending strips 903 shown in FIGS. 19 to 21, the opposite end portions in the X direction have the same width. For the barrier unit 9 of FIG. 19, the percentage of coverage of the barrier part 91 is different from the percentage of coverage of the barrier part 92. For the barrier unit 9 of FIG. 20, the percentages of coverage of the barrier parts 92 and 93 are different. For the barrier unit 9 of FIG. 21, when the barrier unit 9 is divided into three barrier parts 91 to 93, the percentages of coverage for the three barrier parts 91, 92, 93 are close to each other, but the content of the Group III element in the barrier unit 9 changes along the X direction (e.g., the content of the Group III element decreases, then increases, then decreases, and then increases along the X direction). In such case, it can be understood that since the content of the Group III element in the barrier unit 9 changes along the X direction, when the barrier unit 9 shown in FIG. 21 is divided into more than three barrier parts, a percentage of coverage of at least one of the barrier parts can be different from that of an adjacent one of the barrier parts.

The barrier units 9 of FIGS. 22, 23 and 24 are similar to the barrier units 9 of FIGS. 19, 20 and 21, respectively, except that a shape of some of the extending strips 903 and a shape of the base portions 901 are different. For instance, some of the extending strips 903 may have a rounded end opposite to a corresponding one of the base portions 901. Each of the base portion(s) 901 may have rounded recesses 904 (see FIG. 22), and each of the rounded recesses 904 is located between two adjacent ones of the extending strips 903. For the barrier unit 9 of each of FIGS. 22, 23 and 24, the content of the Group III element in the barrier unit 9 changes along the X direction. For the barrier unit 9 of FIG. 22, the percentages of coverage of the barrier parts 91, 92 and 93 are different. For the barrier unit 9 of FIG. 23, the percentages of coverage of the barrier parts 92 and 93 are different. For the barrier unit 9 of FIG. 24, similar to that of FIG. 21, it can be understood that since the content of the Group III element in the barrier unit 9 in FIG. 24 changes along the X direction, when the barrier unit 9 shown in FIG. 24 is divided into more than three barrier parts, a percentage of coverage of at least one of the barrier parts can be different from that of an adjacent one of the barrier parts.

In accordance with some embodiments of the present disclosure, the barrier units 9 exemplarily shown in FIGS. 13 to 24 are each a continuous structure, i.e., the barrier parts are connected to one another. In some other embodiments, the barrier unit 9 may also be a discontinuous structure. FIGS. 25 and 26 show, in accordance with some embodiments in the present disclosure, variant structures of the barrier unit 9 having the discontinuous structure, in which the barrier parts are disconnected from each other. Similarly, the content of the Group III element in the barrier unit 9 of each of FIGS. 25 and 26 changes along the X direction. Referring to FIG. 25, each of the barrier parts 91, 92, 93 includes at least one island feature (represented by one quadrilateral structure). Varying amounts and/or sizes and/or configurations of the island feature(s) may adjust the percentages of coverage of the barrier parts 91 to 93. For instance, in some embodiments, the barrier part 91 includes one island feature configured as a large rectangle; the barrier part 92 includes a first amount of the island features, each of which is configured as a small square; and the barrier part 93 includes a second amount of the small square-shaped island features, wherein the second amount is different from the first amount. The first amount and the second amount of the small square-shaped island features are different so that the barrier parts 92, 93 have different percentages of coverage. The large rectangle of the barrier part 91 has an area greater than a total area of the small square-shaped island features of each of the barrier parts 92, 93, and thus the barrier part 91 has the largest percentage of coverage e. In some embodiments, a percentage of coverage difference between two adjacent ones of the barrier parts 91, 92, 93 may range from about 5% to about 60% (e.g., about 5%, about 10%, about 15%, about 20%, about 25%, about 30%, about 35%, about 40%, about 45%, about 50%, about 55%, or about 60%). In some embodiments, the percentage of coverage of the barrier part 91 may range from about 70% to about 100%; the percentage of coverage of the barrier part 92 may range from about 35% to about 70%; and the percentage of coverage of the barrier part 93 may range from about 5% to about 35%. Other suitable percentages of coverage of the barrier parts 91 to 93 are within the contemplated scope of the present disclosure.

The barrier unit 9 of FIG. 26 is similar to that of FIG. 25, except that arrangements of the island features of the barrier parts 92, 93 are different. For both FIGS. 25 and 26, in each of the barrier parts 92, 93, the island features are arranged into a plurality of rows and columns. In FIG. 25, the island features in one of the rows (or the columns) are aligned with the island features in an adjacent one of the rows (or the columns) in the X direction (or the Y direction). In contrast, in FIG. 26, the island features in one of the rows (or the columns) are staggered with the island features in an adjacent one of the rows (or the columns) in the X direction (or the Y direction).

FIG. 27 is similar to FIG. 15, except that the structure shown in FIG. 27 has merely one of the barrier units 9. Please note that the number of the barrier units 9 may be determined according to practical needs.

FIGS. 28 to 33 exemplarily illustrate steps subsequent to the structure shown in FIG. 13 in accordance with some embodiments. Referring to FIG. 28, after forming the barrier unit(s) 9, a dielectric layer 13 is formed over the barrier layer 5 and the barrier units 9. Possible processes and the materials for forming the dielectric layer 13 are similar to those for forming the dielectric layer 6, and thus details thereof are omitted for sake of brevity.

Referring to FIG. 29, a patterned mask 74 is formed over the dielectric layer 13, and two portions of the dielectric layer 13 that are respectively located at two opposite sides of the barrier units 9 in the X direction are exposed.

Referring to FIG. 30, the two portions of the dielectric layer 13 shown in FIG. 29 are removed (using the patterned mask 74 as an etching mask) to form openings 131. In some embodiments, one of the barrier units 9 is exposed to a corresponding one of the openings 131. In other embodiments, all of the barrier units 9 are entirely covered by the dielectric layer 13 after forming the openings 131. Possible processes for removing the two portions of the dielectric layer 13 are similar to those for removing the dielectric layer 6, and thus details thereof are omitted for sake of brevity.

Referring to FIG. 31, a source electrode 171 and a drain electrode 172 are respectively formed in the openings 131 (see FIG. 30). Afterwards, the patterned mask 74 shown in FIG. 30 is removed, and the dielectric layer 13 is re-exposed. The source electrode 171 and the drain electrode 172 are located on the top surface of the barrier layer 5, and are disposed at two opposite sides of the barrier units 9 in the X direction. In some embodiments, an upper surface of the source electrode 171, an upper surface of the drain electrode 172, and an upper surface of the dielectric layer 13 are substantially coplanar. In some embodiments, the drain electrode 172 may be in contact with an adjacent one of the barrier units 9. In other embodiments, the drain electrode 172 may be spaced apart from the adjacent barrier unit 9.

In some embodiments, in forming the source electrode 171 and the drain electrode 172, a conductive material (not shown, for forming the source electrode 171 and the drain electrode 172) is deposited over the structure shown in FIG. 30 by a deposition process (e.g., sputtering deposition, PVD, CVD, ALD, ALE, or combinations thereof), or other suitable processes. Then, a planarization process (e.g., CMP) is performed to remove an excess amount of the conductive material and the patterned mask 74, thereby forming the source electrode 171 and the drain electrode 172.

In some embodiments, the source electrode 171 and the drain electrode 172 include or are made of aluminum (Al), cobalt (Co), copper (Cu), gold (Au), molybdenum (Mo), platinum (Pt), titanium (Ti), tungsten (W), zirconium (Zr), aluminum copper (AlCu), tantalum nitride (TaN), titanium nitride (TiN), copper silicide (CuSi), nickel silicide (NiSi), or other suitable materials, or combinations thereof. In some embodiments, the source electrode 171 and the drain electrode 172 are made of the same material and are formed using the same patterned mask (e.g., the patterned mask 74). In other embodiments, the source electrode 171 and the drain electrode 172 are made of different materials, and are formed separately using different patterned masks (not shown).

Referring to FIG. 32, a patterned mask 75 is formed over the structure shown in FIG. 31 in a way that exposes a portion of the dielectric layer 13 that is located between the source electrode 171 and the barrier units 9.

Referring to FIG. 33, a gate electrode 15 is formed in the exposed region of the dielectric layer 13 (see FIG. 32, exposed from the patterned mask 75). To be specific, the gate electrode 15 is formed on the top surface of the barrier layer 5 between the source electrode 171 and the barrier units 9. In some embodiments, the upper surface of the source electrode 171, the upper surface of the drain electrode 172, an upper surface of the gate electrode 15 are substantially coplanar. In some embodiments, the gate electrode 15 is in contact with an adjacent one of the barrier units 9. In other embodiments, the gate electrode 15 is spaced apart from the adjacent barrier unit 9. In some embodiments, the source electrode 171 and the gate electrode 15 are separated by a first distance (D1) in the X direction. The drain electrode 172 and the gate electrode 15 are separated by a second distance (D2) in the X direction. The first distance (D1) may be smaller than the second distance (D2).

In some embodiments, in forming the gate electrode 15, the exposed portion of the dielectric layer 13 exposed from the patterned mask 75 (see FIG. 32) is removed by an etching process (e.g., a wet etching process, a dry etching process, or a combination thereof), or other suitable processes to expose a corresponding portion of the barrier layer 5. Then, a conductive material (not shown, for forming the gate electrode 15) is deposited over the exposed portion of the barrier layer 5 by a deposition process (e.g., sputtering deposition, PVD, CVD, ALD, ALE, or combinations thereof), or other suitable processes. Thereafter, a planarization process (e.g., CMP) is performed to remove an excess amount of the conductive material and the patterned mask 75 to re-expose the source electrode 171, the drain electrode 172, and the dielectric layer 13.

In some embodiments, the gate electrode 15 includes or is made of titanium (Ti), titanium nitride (TiN), tantalum nitride (TaN), aluminum (Al), copper (Cu), an aluminum-copper alloy (AlCu), nickel silicide (NiSi), cobalt silicide (CoSi), molybdenum (Mo), tungsten (W), cobalt (Co), zirconium (Zr), platinum (Pt), gold (Au), combinations thereof, or other suitable materials.

FIGS. 34 to 39 are perspective views of variations of structures in accordance with some embodiments, and are similar to that shown in FIG. 33 (the substrate 1, the buffer layer 2, the channel layer 3, and the dielectric layer 13 are not drawn in FIGS. 34 to 39), except that the structures shown in FIGS. 34 to 39 merely has one barrier unit 9. The barrier units 9 in FIGS. 34, 35, 37 are respectively similar to those described with reference to FIGS. 13, 14, 16. The barrier unit 9 of FIG. 36 is similar to that described with reference to FIG. 16, except that the base portion 901 is omitted. In each of FIGS. 36 and 37, the barrier unit 9 is connected to the drain electrode 172 and the extending strips 903 are tapered toward the gate electrode 15. The barrier unit 9 of FIGS. 38 and 39 are respectively similar to those described with reference to FIGS. 36 and 37, except that in each of FIGS. 38 and 39, the barrier unit 9 is connected to the gate electrode 15, and the extending strips 903 are tapered toward the drain electrode 172.

FIGS. 40 to 43 exemplarily illustrate steps subsequent to the structure shown in FIG. 33 in accordance with some embodiments. Referring to FIG. 40, a dielectric layer 131 is formed over the structure shown in FIG. 33 to cover the source electrode 171, the gate electrode 15, and the drain electrode 172. Possible processes and materials for forming the dielectric layer 131 are similar to those for forming the dielectric layer 13, and thus details thereof are omitted for the sake of brevity.

Referring to FIG. 41, a conductive layer 18 is formed over the dielectric layer 131. The conductive layer 18 may be formed by a deposition process (e.g., sputtering deposition, PVD, CVD, ALD, ALE, or combinations thereof), or other suitable processes. In some embodiments, the conductive layer 18 includes or is made of aluminum (Al), cobalt (Co), copper (Cu), tantalum (Ta), titanium (Ti), tungsten (W), ruthenium (Ru), or other suitable materials, or combinations thereof.

Referring to FIG. 42, a patterned mask 76 is formed over the conductive layer 18 in a way that exposes to expose portions of the conductive layer 18.

Referring to FIG. 43, the conductive layer 18 is patterned into a field plate unit 180 through the patterned mask 76 (see FIG. 42). The field plate unit 180 is formed above the top surface of the barrier layer 5 between the gate electrode 15 and the drain electrode 172. In some embodiments, the field plate unit 180 is configured as a patterned plate structure, and has a profile that changes along the X direction.

In some embodiments, in forming the field plate unit 180, the conductive layer 18 is patterned by an etching process (e.g., a reactive ion etching process, an inductively coupled plasma etching process, an electron cyclotron resonance etching process, a neutral beam etching process, a wet etching process, or combinations thereof), or other suitable processes to remove the portions of the conductive layer 18 exposed from the patterned mask 76. Then, the patterned mask 76 shown in FIG. 42 is removed by a removing process (e.g., an ashing process) or other suitable processes, and the field plate unit 180 is obtained.

FIGS. 44 to 52 are top views illustrating different patterns for the field plate unit 180 in accordance with some embodiments in the present disclosure. In some embodiments, the field plate unit 180 is configured as a patterned plate structure. The patterned plate structure of the field plate unit 180 is independent from, and may be the same as or different from the patterned plate structures of the barrier units 9.

In FIG. 44, a portion of the top surface of the barrier layer 5 (see FIG. 43) for forming the field plate unit 180 thereabove is located between the gate electrode 15 and the drain electrode 172 (see FIG. 43), and includes regions 181, 182, 183 (shown by dotted lines) that are of the same size (and the same area) and that are displaced from each other in the X direction. Please note that the regions 181, 182, 183 may overlap, or may be spaced apart from the regions 51, 52, 53 discussed in FIGS. 16 to 26. The field plate unit 180 is divided into plate parts 181A, 182A, 183A, each of which is disposed above and covers a corresponding one of the regions 181, 182, 183. Please note that the number of the regions equals to the number of the plate parts, and is not limited to three. A projection of each of the plate parts 181A, 182A, 183A on the corresponding one of the regions 181, 182, 183 has a percentage of coverage out of an area of the corresponding one of the regions 181, 182, 183. The percentage of coverage of one of the plate parts 181A, 182A, 183A is different from the percentage of coverage of an adjacent one of the plate parts 181A, 182A, 183A. In other words, a percentage of coverage of a projection of each of the plate parts 181A to 183A onto a corresponding one of the regions 181 to 183 over an area of the corresponding one of the regions 181 to 183 is different from a percentage of coverage of a projection of an adjacent one of the plate parts 181A to 183A onto a corresponding one of the regions 181 to 183 over an area of the corresponding one of the regions 181 to 183. Hereinafter, a percentage of coverage of a certain plate part (e.g., 181A) refers to a percentage of a projection of the certain plate part (e.g., 181A) onto a corresponding one of the regions (e.g., 1811) over an area of the corresponding one of the regions (e.g., 181). The patterned plate structure of the field plate unit 180 shown in FIG. 44 is similar to the patterned plate structure of the barrier unit 9 described with reference to FIG. 16, and includes a base portion 1801 and an extending portion 1802 (having extending strips 1803) that are respectively similar to the base portion 901 and the extending portion 902 (having the extending strips 903) described in FIG. 16. The patterned plate structures of the field plate units 180 shown in FIGS. 45 to 52 are respectively similar to the patterned plate structures of the barrier units 9 described with reference to FIGS. 17 to 24. For instance, the base portions 1801, the extending portions 1802 (having the extending strips 1803) shown in FIGS. 45 to 52 are respectively similar to the base portions 901 and the extending portions 902 (having the extending strips 903) shown in FIGS. 17 to 24. Other details regarding the different variations of the patterned plate structure are not repeated for the sake of brevity.

FIGS. 53 to 62 exemplarily illustrate steps subsequent to the structure shown in FIG. 43 in accordance with some embodiments. Referring to FIG. 53, a dielectric layer 132 is formed over the structure shown in FIG. 43 to cover the field plate unit 180 using a deposition process followed by a planarization process (e.g., CMP or other suitable processes). Possible materials and deposition processes for forming the dielectric material is similar to those for forming the dielectric layer 13, and thus details thereof are omitted for the sake of brevity.

Referring to FIG. 54, a conductive layer 19 is formed over the dielectric layer 132. A patterned mask 77 is formed on the conductive layer 19 in a way that exposes portions of the conductive layer 19. Possible materials and processes for forming the conductive layer 19 and the patterned mask 77 are similar to those of forming the conductive layer 18 and the patterned mask 71, and thus the details thereof are omitted for the sake of brevity.

Referring to FIG. 55, the conductive layer 19 is patterned into a field plate unit 190 through the patterned mask 77 (see also FIG. 54), and then the patterned mask 77 is removed. Similar to the field plate unit 180, the field plate unit 190 is also located above the top surface between the gate electrode 15 and the drain electrode 172, and has a profile that changes along the X direction. A projection of the field plate units 180, 190 on the top surface of the barrier layer 5 are proximal to and distal to the gate electrode 15, respectively. A distance between the field plate unit 180 and the top surface of the barrier layer 5 may be the same as or different from a distance between the field plate unit 190 and the top surface of the barrier layer 5. The field plate unit 190 may be configured as a patterned plate structure similar to those described in FIGS. 44 to 52, or other suitable patterns. The field plate units 180, 190 may have the same or different patterns based on practical needs. Possible materials and processes for forming the second field plate unit 190 are similar to those for forming the first field plate unit 180 described with reference to FIGS. 42 and 43, and thus the details thereof are omitted for sake of brevity. Please note that the number of the field plate units may be determined according to practical needs, and may be formed by repeating steps illustrated in FIGS. 54 and 55.

Referring to FIG. 56, a dielectric layer 141 is formed over the structure shown in FIG. 55 to cover the field plate unit 190. Possible materials and processes for forming the dielectric layer 141 is similar to those for forming the dielectric layer 132, and thus the details thereof are omitted for the sake of brevity.

Referring to FIG. 57, openings 133, 135, 137, 139 are formed to expose the source electrode 171, the field plate unit 180, the field plate unit 190, and the drain electrode 172, respectively.

In some embodiments, the openings 133, 135, 137, 139, may be formed by one or more photolithography process(es) and one or more etching process(es) (e.g., a reactive ion etching process, an inductively coupled plasma etching process, an electron cyclotron resonance etching process, a neutral beam etching process, a wet etching process, or combinations thereof).

Referring to FIG. 58, contacts 201, 203, 205, 207 are formed in the openings 133, 135, 137, 139 (see FIG. 57), respectively. Each of the contacts 201, 203, 205, 207 cover and is in contact with a respective one of the source electrode 171, the first field plate unit 180, the second field plate unit 190 and the drain electrode 172.

In some embodiments, in forming the contacts 201, 203, 205, 207, a conductive material (not shown, for forming the contacts 201, 203, 205, 207) is deposited by a deposition process (e.g., sputtering deposition, PVD, CVD, ALD, ALE, or combinations thereof), or other suitable processes to fill the openings 133, 135, 137, 139. Then, a planarization process (e.g., CMP) is performed to remove an excess amount of the conductive material so as to expose the dielectric layer 141.

In some embodiments, the contacts 201, 203, 205, 207 include or are made of aluminum (Al), cobalt (Co), copper (Cu), tantalum (Ta), titanium (Ti), tungsten (W), ruthenium (Ru), or other suitable materials, or combinations thereof.

Referring to FIG. 59, a conductive layer 22 is formed over the dielectric layer 13 and the contacts 201, 203, 205, 207 using a deposition process (e.g., sputtering deposition, PVD, CVD, ALD, ALE, or combinations thereof), or other suitable processes. In some embodiments, the conductive layer 22 includes or is made of aluminum (Al), cobalt (Co), copper (Cu), tantalum (Ta), titanium (Ti), tungsten (W), ruthenium (Ru), or other suitable materials, or combinations thereof,.

Referring to FIG. 60, a patterned mask 78 is formed over the conductive layer 22 in a way that exposes a portion of the conductive layer 22.

Referring to FIG. 61, the conductive layer 22 is patterned into two conductive portions 221, 222 through the patterned mask 78 (see FIG. 60), and then the patterned mask 78 is removed. The two conductive portions 221, 222 are spaced apart from each other. The field plate unit 180 is connected to the source electrode 171 through the conductive portion 221 and the contacts 201, 203. The field plate unit 190 is connected to the drain electrode 172 through the conductive portion 222 and the contacts 205, 207. Possible processes for patterning the conductive layer 22 and removing the patterned mask 78 are similar to those for patterning the conductive layer 18 and removing the patterned mask 76 described with reference to FIGS. 42 and 43, and thus the details thereof are omitted for the sake of brevity.

Referring to FIG. 62, a dielectric layer 142 is formed over the structure shown in FIG. 61. Possible materials and processes for forming the dielectric layer 142 is similar to those of forming the dielectric layer 132, and thus the details thereof are omitted for the sake of brevity. The semiconductor structure of the present disclosure is therefore obtained.

FIG. 63 shows a variation of the semiconductor structure in accordance with some embodiments. The structure shown in FIG. 63 is similar to the structure shown in FIG. 62, except that the structure shown in FIG. 63 further includes a field plate unit 200. In some embodiments, the field plate unit 200 is connected to the conductive portion 221 through a contact 209 (which may be formed together with the contacts 201, 203, 205, 207 described with reference to FIGS. 57 and 58). In other embodiments not shown, the field plate unit 200 may be connected to the conductive portion 222. In some embodiments, the field plate unit 200 is located at a level same as that of the field plate unit 190, and is formed simultaneously with the field plate unit 190. The field plate unit 200 may be formed by adjusting the patterning process described in FIGS. 54 and 55, while other details may remain the same. It should be noted that the number of field plate unit(s) in the present disclosure may be determined according to practical needs. In some embodiments, there may be only one of the field plate units 180, 190, 200. In other embodiments, there may be more than three of the field plate units. Please note that the field plate units may be located at the same or different height(s). The field plate units may have the same or different pattern(s). Other suitable numbers of and/or configurations for the field plate unit(s) are within the contemplated scope of the present disclosure.

FIG. 64 shows a perspective view of a variation of structure in accordance with some embodiments. The structure of FIG. 64 is similar to the structure shown in FIG. 62 (the substrate 1, the buffer layer 2, the channel layer 3, and the dielectric layers 13, 131, 132, 141, 142 are not drawn in FIG. 64), except that in FIG. 64, (i) the field plate unit 190 shown in FIG. 62 is not formed, (ii) the conductive portion 222 and the contacts 205, 207 shown in FIG. 62 are not formed, and (iii) only one of the barrier units 9 is formed. Regarding (i) and (ii), please also note that when the field plate unit(s) are designed not to be connected to the drain electrode 172 (or the source electrode 171), the conductive portion 222 (or the conductive portion 221) and the contacts 205, 207 (or the contacts 201, 203) may also be omitted. The semiconductor structure shown in FIG. 65 is similar to that shown in FIG. 64 (the substrate 1, the buffer layer 2, the channel layer 3, and the dielectric layers 13, 131, 132, 141, 142 are not drawn in FIG. 65), except that the barrier unit 9 has a different configuration.

FIG. 66 shows a perspective view of a variant structure in accordance with some embodiments. The structure of FIG. 66 is similar to the structure shown in FIG. 65 (the substrate 1, the buffer layer 2, the channel layer 3, and the dielectric layers 13, 131, 132, 141, 142 are not drawn in FIG. 66), except that the barrier unit 9 is omitted. In accordance with some embodiments of the present disclosure, the semiconductor structure may include one of the barrier unit, the field plate unit, and a combination thereof.

FIG. 67 shows a perspective view of a variant structure in accordance with some embodiments. The structure of FIG. 67 is similar to the structure shown in FIG. 62 (the substrate 1, the buffer layer 2, the channel layer 3, and the dielectric layers 13, 131, 132, 141, 142 are not drawn in FIG. 67), except that in FIG. 67, (i) the field plate unit 180 shown in FIG. 62 is not formed, (ii) the conductive portion 221 and the contacts 201, 203 shown in FIG. 62 are not formed, and (iii) the barrier units 9 are not formed.

Referring to the flow diagram shown in FIG. 1, step 101 is exemplified by the structure shown in FIGS. 2 to 27; step 102 is exemplified by the structure shown in FIGS. 28 to 31; step 103 is exemplified by the structure shown in FIGS. 32 to 39; and step 104 is exemplified by the structure shown in FIGS. 40 to 67.

In sum, in the present disclosure, both the barrier units 9 and the field plate units 180, 190, 200 are configured to modify a surface electric field between the gate electrode 15 and the drain electrode 172 along the X direction, so as to obtain an evenly distributed surface electric field (i.e., a relatively gentle slope could be observed in a surface electric field distribution graph between the gate electrode 15 and the drain electrode 172 along the X direction). The semiconductor structure including such barrier unit(s) 9 and/or the field plate unit(s) 180, 190, 200 may achieve a gradient reduced surface field (RESURF) behavior, and have a large breakdown voltage, which is beneficial to applications in high-performance power devices. In addition, the barrier unit(s) 9 and the field plate unit(s) 180, 190, 200 may be provided by simple patterning process(es), and thus a relatively low manufacturing cost is expected.

To be specific, in the barrier units 9 of the present disclosure, the content of the Group III element changes along the X direction. Varying the Group III element content along the X direction alters a polarization effect at an interface between the channel layer 3 and a combination of the barrier layer 5 and the barrier unit 9, so as to alter a two dimensional electron gas (2DEG) formed at the interface. As such, a charge carrier density at the interface along the X direction could be controlled to evenly redistribute the surface electric field between the gate electrode 15 and the drain electrode 172, and to achieve the gradient reduced surface field (RESURF) behavior.

The field plate units 180, 190, 200 of the present disclosure having the profile thereof that changes along the X direction enables a gradient capacitance depletion along the X direction, so as to evenly redistribute the surface electric field between the gate electrode 15 and the drain electrode 172, and to achieve the gradient reduced surface field (RESURF) behavior. In contrast, in some cases where the field plate unit of the semiconductor structure has the same profile along the X direction, redistribution of the surface electric field is ineffective and merely occurs at boundaries, e.g., edges of the gate electrode and the drain electrode. A steep gradient (i.e., a sharp peak) is observed in the surface electric field distribution graph. Such field plate unit is ineffective in preventing a dielectric breakdown of the semiconductor structure.

In accordance with some embodiments of the present disclosure, a method for manufacturing a semiconductor structure includes: forming a channel layer on a substrate, the channel layer including a first III-V compound; forming a barrier layer on the channel layer opposite to the substrate, the barrier layer including a second III-V compound, and having a top surface opposite to the channel layer, the top surface extending along a first direction; forming a barrier unit on the top surface, the barrier unit including a third III-V compound, and having a content of a Group III element changing along the first direction; forming a source electrode and a drain electrode on the top surface of the barrier layer, the source electrode and the drain electrode being disposed at two opposite sides of the barrier unit in the first direction; and forming a gate electrode on the top surface of the barrier layer between the source electrode and the barrier unit.

In accordance with some embodiments of the present disclosure, a portion of the top surface of the barrier layer is located between the gate electrode and the drain electrode for forming the barrier unit, and is divided into regions that are of equal size and that are displaced from each other in the first direction; and the barrier unit includes barrier parts, each of which covers a corresponding one of the regions of the top surface, a projection of each of the barrier parts on the corresponding one of the regions having a percentage of coverage out of an area of the corresponding one of the regions, the percentage of coverage of one of the barrier parts being different from the coverage percentage of an adjacent one of the barrier parts.

In accordance with some embodiments of the present disclosure, each of the barrier parts includes at least one island feature.

In accordance with some embodiments of the present disclosure, one of the barrier parts includes a first amount of the island features, and another one of the barrier parts includes a second amount of the island features, the first amount being different from the second amount.

In accordance with some embodiments of the present disclosure, the barrier unit is configured as a patterned plate structure.

In accordance with some embodiments of the present disclosure, the patterned plate structure includes a base portion disposed adjacent to one of the gate electrode and the drain electrode, and an extending portion extending from the base portion toward the other one of the gate electrode and the drain electrode, the extending portion including extending strips that are displaced from each other in a second direction different from the first direction.

In accordance with some embodiments of the present disclosure, each of the extending strips is tapered toward the other one of the gate electrode and the drain electrode.

In accordance with some embodiments of the present disclosure, each of the extending strips has a rounded end opposite to the base portion.

In accordance with some embodiments of the present disclosure, the base portion has rounded recesses each of which is located between two adjacent ones of the extending strips.

In accordance with some embodiments of the present disclosure, a portion of the top surface of the barrier layer is located between the gate electrode and the drain electrode for forming the barrier unit, and is divided into regions that are displaced from each other in the first direction; the barrier unit includes barrier parts, each of which is disposed on a corresponding one of the regions of the top surface; and a concentration of the Group III element of one of the barrier parts is different from a concentration of the Group III element of an adjacent one of the barrier parts.

In accordance with some embodiments of the present disclosure, a portion of the top surface of the barrier layer is located between the gate electrode and the drain electrode for forming the barrier unit, and is divided into regions that are displaced from each other in the first direction; the barrier unit includes barrier parts, each of which is disposed on a corresponding one of the regions of the top surface; and a thickness of one of the barrier parts is different from a thickness of an adjacent one of the barrier parts.

In accordance with some embodiments of the present disclosure, a method for manufacturing a semiconductor structure, includes: forming a channel layer on a substrate, the channel layer including a first III-V compound; forming a barrier layer on the channel layer, the barrier layer including a second III-V compound, and having a top surface opposite to the channel layer, the top surface extending along a first direction; forming a source electrode, a gate electrode and a drain electrode on the barrier layer, the source electrode, the gate electrode and the drain electrode being spaced apart along the first direction in such order; and forming a first field plate unit above the top surface between the gate electrode and the drain electrode, the first field plate unit having a profile that changes along the first direction.

In accordance with some embodiments of the present disclosure, a portion of the top surface of the barrier layer is located between the gate electrode and the drain electrode for forming the barrier unit, and is divided into regions that are of equal size and that are displaced from each other in the first direction; and the first field plate unit includes plate parts, each of which covers a corresponding one of the regions of the top surface, a projection of each one of the plate parts on the corresponding one of the regions having a percentage of coverage out of an area of the corresponding one of the regions, the percentage of coverage of one of the plate parts being different from the coverage percentage of an adjacent one of the plate parts.

In accordance with some embodiments of the present disclosure, the first field plate unit is configured as a patterned plate structure.

In accordance with some embodiments of the present disclosure, the method further includes: forming a second field plate unit above the top surface between the gate electrode and the drain electrode, the second field plate unit having a profile that changes along the first direction, a projection of the first field plate unit on the top surface and a projection of the second field plate unit on the top surface being proximal to and distal to the gate electrode, respectively.

In accordance with some embodiments of the present disclosure, a distance between the first field plate unit and the top surface is different from a distance between the second field plate unit and the top surface.

In accordance with some embodiments of the present disclosure, the first field plate unit and the second field plate unit have different shapes in top view.

In accordance with some embodiments of the present disclosure, the first field plate unit is connected to one of the source electrode and the drain electrode.

In accordance with some embodiments of the present disclosure, a semiconductor structure includes a channel layer that is disposed on a substrate, a barrier layer on the channel layer, a source electrode, a gate electrode, a drain electrode, a barrier unit, and a field plate unit. The channel layer includes a first III-V compound. The barrier layer includes a second III-V compound, and has a top surface opposite to the channel layer. The top surface extends along a first direction. The source electrode, the gate electrode, and the drain electrode are disposed on the barrier layer, and are spaced apart along the first direction in such order. The barrier unit is disposed on the top surface between the gate electrode and the drain electrode. The barrier unit includes a third III-V compound, and has a content of a Group III element changing along the first direction. The field plate unit is disposed above the top surface between the gate electrode and the drain electrode. The field plate unit has a profile that changes along the first direction.

In accordance with some embodiments of the present disclosure, the field plate unit is configured as a patterned plate structure.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for manufacturing a semiconductor structure, comprising:
growing a channel layer on a substrate, the channel layer including a first III-V compound;
growing a barrier layer on the channel layer opposite to the substrate, the barrier layer including a second III-V compound, and having a top surface opposite to the channel layer, the top surface extending along a first direction;
depositing a barrier material layer on the top surface of the barrier layer, and partially removing the barrier material layer so as to obtain a barrier unit on a first portion of the top surface of the barrier layer, the barrier unit including a third III-V compound, and having a content of a Group III element changing along the first direction;
depositing a dielectric layer over the barrier unit;
patterning the dielectric layer to form two openings that respectively expose two second portions of the top surface of the barrier layer;
depositing a first conductive material over the dielectric layer, and removing an excess portion of the first conductive material to form the first conductive material into a source electrode and a drain electrode respectively on the two second portions of the top surface of the barrier layer, the source electrode and the drain electrode being disposed at two opposite sides of the barrier unit in the first direction; and
patterning the dielectric layer to expose a third portion of the top surface of the barrier layer;
depositing a second conductive material over the dielectric layer to cover the third portion of the top surface of the barrier layer and removing an excess portion of the second conductive material so as to form the second conductive material into gate electrode on the third portion of the top surface of the barrier layer between the source electrode and the barrier unit.

2. The method of claim 1, wherein:
the first portion of the top surface of the barrier layer is located between the gate electrode and the drain electrode for forming the barrier unit, and is divided into regions that are of equal size and that are displaced from each other in the first direction; and
the barrier unit includes barrier parts, each of which covers a corresponding one of the regions of the first portion of the top surface, a projection of each of the barrier parts on the corresponding one of the regions having a percentage of coverage out of an area of the corresponding one of the regions,
the percentage of coverage of one of the barrier parts being different from the percentage of coverage of an adjacent one of the barrier parts.

3. The method of claim 2, wherein each of the barrier parts includes at least one island feature.

4. The method of claim 3, wherein one of the barrier parts includes a first amount of the island features, and another one of the barrier parts includes a second amount of the island features, the first amount being different from the second amount.

5. The method of claim 1, wherein the barrier unit is configured as a patterned plate structure.

6. The method of claim 5, wherein the patterned plate structure includes
a base portion disposed adjacent to one of the gate electrode and the drain electrode, and
an extending portion extending from the base portion toward the other one of the gate electrode and the drain electrode, the extending portion including extending strips that are displaced from each other in a second direction different from the first direction.

7. The method of claim 6, wherein each of the extending strips is tapered toward the other one of the gate electrode and the drain electrode.

8. The method of claim 6, wherein each of the extending strips has a rounded end opposite to the base portion.

9. The method of claim 6, wherein the base portion has rounded recesses each of which is located between two adjacent ones of the extending strips.

10. The method of claim 1, wherein:
the first portion of the top surface of the barrier layer is located between the gate electrode and the drain electrode for forming the barrier unit, and is divided into regions that are displaced from each other in the first direction;
the barrier unit includes barrier parts, each of which is disposed on a corresponding one of the regions of the first portion of the top surface, the barrier parts being formed separately, the barrier material layer including barrier material portions, each of which is deposited and partially removed to obtain a corresponding one of the barrier parts; and
a concentration of the Group III element of one of the barrier parts is different from a concentration of the Group III element of an adjacent one of the barrier parts.

11. The method of claim 1, wherein:
the first portion of the top surface of the barrier layer is located between the gate electrode and the drain electrode for forming the barrier unit, and is divided into regions that are displaced from each other in the first direction;
the barrier unit includes barrier parts, each of which is disposed on a corresponding one of the regions of the first portion of the top surface, the barrier parts being formed separately, the barrier material layer including barrier material portions, each of which is deposited and partially removed to obtain a corresponding one of the barrier parts; and
a thickness of one of the barrier parts is different from a thickness of an adjacent one of the barrier parts.

12. A method for manufacturing a semiconductor structure, comprising:
growing a channel layer on a substrate, the channel layer including a first III-V compound;
growing a barrier layer on the channel layer, the barrier layer including a second III-V compound, and having a top surface opposite to the channel layer, the top surface extending along a first direction;
depositing a first dielectric layer over the barrier layer;
patterning the first dielectric layer to form two openings that respectively expose two first portions of the top surface of the barrier layer;
depositing a first conductive material over the first dielectric layer, and removing an excess portion of the first conductive material to form the first conductive material into a source electrode and a drain electrode respectively on the two second portions of the top surface of the barrier layer;
patterning the first dielectric layer to expose a second portion of the top surface of the barrier layer;
depositing a second conductive material over the first dielectric layer to cover the second portion of the top surface of the barrier layer and removing an excess portion of the second conductive material so as to form the second conductive material into gate electrode on the second portion of the top surface of the barrier layer;
depositing a second dielectric layer over the first dielectric layer to cover the source electrode, the drain electrode and the gate electrode;
depositing a first conductive layer over the second dielectric layer;
patterning the first conductive layer into a first field plate unit that is located above the top surface of the barrier layer between the gate electrode and the drain electrode, the first field plate unit having a profile that changes along the first direction.

13. The method of claim 12, wherein:
the first field plate unit is located above a third portion of the top surface of the barrier layer, the third portion being divided into regions that are of equal size and that are displaced from each other in the first direction; and
the first field plate unit includes plate parts, each of which covers a corresponding one of the regions of the third portion of the top surface, a projection of each of the plate parts on the corresponding one of the regions having a percentage of coverage out of an area of the corresponding one of the regions,
the percentage of coverage of one of the plate parts being different from the percentage of coverage of an adjacent one of the plate parts.

14. The method of claim 12, wherein the first field plate unit is configured as a patterned plate structure.

15. The method of claim 12, further comprising:
depositing a third dielectric layer over the second dielectric layer to cover the first field plate unit;
depositing a second conductive layer over the third dielectric layer;
patterning the second conductive layer into second field plate unit that is located above the top surface of the barrier layer between the gate electrode and the drain electrode, the second field plate unit having a profile that changes along the first direction,
a projection of the first field plate unit on the top surface and a projection of the second field plate unit on the top surface being proximal to and distal to the gate electrode, respectively.

16. The method of claim 15, wherein a distance between the first field plate unit and the top surface is different from a distance between the second field plate unit and the top surface.

17. The method of claim 15, wherein the first field plate unit and the second field plate unit have different shapes in top view.

18. The method of claim 15, wherein the first field plate unit is connected to one of the source electrode and the drain electrode.

19. A semiconductor structure, comprising:
a channel layer disposed on a substrate, the channel layer including a first III-V compound;
a barrier layer on the channel layer, the barrier layer including a second III-V compound, and having a top surface opposite to the channel layer, the top surface extending along a first direction;
a source electrode, a gate electrode and a drain electrode that are disposed on the barrier layer, and that are spaced apart along the first direction in such order;
a barrier unit disposed on the top surface between the gate electrode and the drain electrode, the barrier unit including a third III-V compound, and having a content of a Group III element changing along the first direction; and
a field plate unit disposed above the top surface between the gate electrode and the drain electrode, the field plate unit having a profile that changes along the first direction.

20. The semiconductor structure of claim 19, wherein the field plate unit is configured as a patterned plate structure.
